(19) United States
(12) Patent Application Publication
(10) Pub. No.: US 2012/0073651 A1
(43) Pub. Date: Mar. 29, 2012

(54) PHOTOELECTRIC CONVERSION ELEMENT

(75) Inventors: Akira Fujimoto, Kawasaki-Shi (JP); Eishi Tsutsumi, Kawasaki-Shi (JP); Tsutomu Nakanishi, Tokyo (JP); Kumi Masunaga, Kawasaki-Shi (JP); Kenji Nakamura, Kawasaki-Shi (JP); Koji Asakawa, Kawasaki-Shi (JP)

(73) Assignee: Kabushiki Kaisha Toshiba, Tokyo (JP)

(21) Appl. No.: 13/228,754

(22) Filed: Sep. 9, 2011

(30) Foreign Application Priority Data
Sep. 29, 2010 (JP) 2010-219991

(51) Int. Cl. H01L 31/0368; H01L 31/02

(52) U.S. Cl. 136/258; 136/252

(57) ABSTRACT

A photoelectric conversion element according to an embodiments includes: a first metal layer; a semiconductor layer formed on the first metal layer; a second metal layer formed on the semiconductor layer, the second metal layer comprising a porous thin film with a plurality of openings each having a mean area not smaller than 80 nm² and not larger than 0.8 μm² or miniature structures having a mean volume not smaller than 4 nm³ and not larger than 0.52 μm³; and a wavelength converting layer formed between the semiconductor layer and the second metal layer, at least a refractive index of a portion of the wavelength converting layer being lower than a refractive index of a material of the semiconductor layer, the portion being at a distance of 5 nm or shorter from an end portion of the second metal layer.

### CROSS-REFERENCE TO RELATED APPLICATION

This application is based upon and claims the benefit of priority from prior Japanese Patent Application No. 2010-219991 filed on Sep. 29, 2010 in Japan, the entire contents of which are incorporated herein by reference.

### FIELD

Embodiments described herein relate generally to a photoelectric conversion element.

### BACKGROUND

In recent years, as a means to realize higher-efficiency solar cells, there has been a technique suggested for increasing carrier excitation by generating intensified electric fields through plasmon resonance caused by metallic nanostructures. Extremely-highly intensified electric fields are generated within several tens of nanometers immediately beneath metallic microscopic structures, and therefore, such intensified electric fields are suited for enhancing the efficiencies of thin-film solar cells.

For example, in cases where metallic nanostructures are formed in Si solar cells, peak wavelengths of electric field enhancement are often observed at wavelengths longer than 1000 nm. Since the absorption wavelength range of Si solar cells is between 300 nm and 1150 nm, the intensified electric fields are hardly effective. To make a peak wavelength of electric field enhancement shift to a shorter wavelength, the pitch of nanostructures needs to be made shorter. As a result, processing becomes more difficult.

### BRIEF DESCRIPTION OF THE DRAWINGS

FIGS. 1(a) and 1(b) are diagrams showing an intensified field effect generated by the plasmon resonance caused by a metallic microscopic structure;

FIGS. 2(a) and 2(b) are diagrams showing local electric fields generated by a metallic microscopic structure;

FIG. 3(a) is a cross-sectional view showing a solar cell;

FIG. 3(b) is a diagram showing the relationship between the thickness of a wavelength converting layer and an absorption spectrum;

FIG. 4(a) is a cross-sectional view showing another solar cell;

FIG. 4(b) is a diagram showing the relationship between the thickness of the wavelength converting layer and the absorption spectrum;

FIGS. 5(a) through 5(f) are diagrams showing an example of a method of manufacturing the solar cell shown in FIG. 3(a);

FIGS. 6(a) through 6(f) are diagrams showing an example of a method of manufacturing the solar cell shown in FIG. 3(a);

FIGS. 7(a) through 7(f) are diagrams showing an example of a method of manufacturing the solar cell shown in FIG. 4(a);

FIGS. 8(a) through 8(f) are diagrams showing an example of a method of manufacturing yet another solar cell;

FIGS. 9(a) through 9(f) are diagrams showing an example of a method of manufacturing yet another solar cell; and

FIGS. 10(a) through 10(f) are diagrams showing an example of a method of manufacturing yet another solar cell.

### DETAILED DESCRIPTION

A photoelectric conversion element according to an embodiment includes: a first metal layer; a semiconductor layer formed on the first metal layer; a second metal layer formed on the semiconductor layer, the second metal layer comprising a porous thin film with a plurality of openings each having a mean area not smaller than 80 nm² and not larger than 0.8 μm² or miniature structures having a mean volume not smaller than 4 nm³ and not larger than 0.52 μm³; and a wavelength converting layer formed between the semiconductor layer and the second metal layer, at least a refractive index of a portion of the wavelength converting layer being lower than a refractive index of a material of the semiconductor layer, the portion being at a distance of 5 nm or shorter from an end portion of the second metal layer.

The following is a detailed description of embodiments, with reference to the accompanying drawings. The basic principles of the embodiments are described in detail.

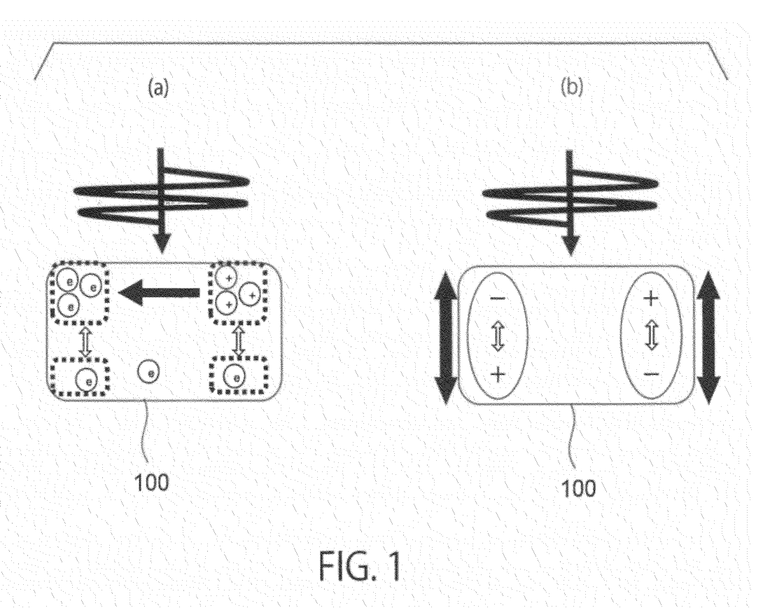

First, an intensified field effect generated by the plasmon resonance of a metallic microscopic structure (a nanostructure) is described. FIGS. 1(a) and 1(b) are diagrams showing a microscopic structure that a light beam is emitted thereonto. It is a known fact that, when a light beam is emitted onto a metallic microscopic structure 100, a surface plasmon is excited if the size of the microscopic structure 100 is equivalent to or smaller than the wavelength of the incident light. As light is emitted onto the microscopic structure 100, free electrons in the microscopic structure 100 vibrate perpendicularly to the traveling direction of light. At this point, electron dense regions and electron sparse regions are formed in the end portions of the microscopic structure 100 due to the vibration of the free electrons, as shown in FIG. 1(a). As a result, as shown in FIG. 1(b), local electric fields that vibrate parallel to the traveling direction of light is generated in the vicinities of the end portions of the microscopic structure 100. The local electric fields generated at this point are several hundreds of times larger than the electric field generated by the incident light, and this intensified electric field is believed to facilitate generation of electron-hole pairs in the photoelectric conversion element.

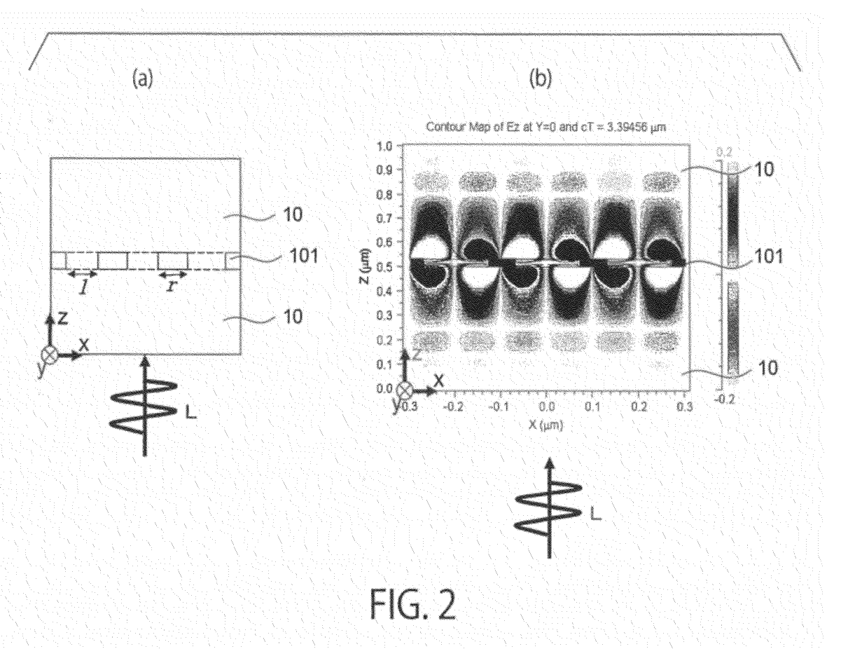

FIGS. 2(a) and 2(b) show the strong local electric fields caused by the metallic microscopic structure 100. The microscopic structure 100 can be a mesh-like structure (a porous thin film) or miniature structures or the like, but an Al mesh is described as an example herein. As shown in FIG. 2(a), a structure of Si/AI (30 nm)/air was hypothetically formed. That is, a structure was hypothetically formed by placing a mesh 101 made of Al between a pair of Si layers 10, and filling the spaces in the Al mesh 101 sandwiched by the Si layers 10 with Si. The opening size r of the Al mesh 101 was fixed at 100 nm, and the pitch l was fixed at 200 nm. FIG. 2(b) shows the results of a simulation performed on the structure using the FDTD (Finite Difference Time Domain) method. FIG. 2(b) shows the electric field intensity obtained when incident light L (λ=1000 nm in the traveling direction) is emitted onto the structure. As can be seen from the results of the simulation, the electric fields were intensified in the vicinities of the end portions of the Al mesh 101, and local electric fields were generated.

Although a case where the microscopic structure is a mesh-like structure has been described, the same phenomenon occurs in a case where particulate metallic members are employed. Electric fields are also intensified in the vicinities of the end portions of the particulate metallic members, and local electric fields are generated.

For example, it has become apparent that, where a mesh-like microscopic structure is used, local electric fields are generated by forming openings, each of which having a mean area of not smaller than 80 nm² and not larger than 0.8 μm². The mesh-like microscopic structure preferably has a thickness of not smaller than 2 nm and not larger than 200 nm, and preferably has openings with a mean diameter of not smaller than 10 nm and not larger than 1 μm. The mean width of the metallic member existing between two adjacent openings is preferably not smaller than 10 nm and not larger than 1 μm.

It has become apparent that, where miniature structures are used as the microscopic structure, local electric fields are generated by setting the mean volume at not less than 4 nm³ and not more than 0.52 μm³. Two or more miniature structures are employed. The mean interval between two adjacent miniature structures is preferably 0.62×(the volume of one miniature structure)^{1/3} or longer where the volume of each miniature structure is less than 4×10⁻³ μm³, and is preferably not shorter than 100 nm and not longer than 1 μm where the volume of each miniature structure is 4×10⁻³ μm³ or greater.

Next, a simulation using the FDTD method was performed to examine shifting of the peak wavelengths of the intensified electric fields in structures in which a material with a low refractive index or air is formed in a stripe pattern, a pillar-like pattern, or a layer-like pattern immediately below a microscopic structure.

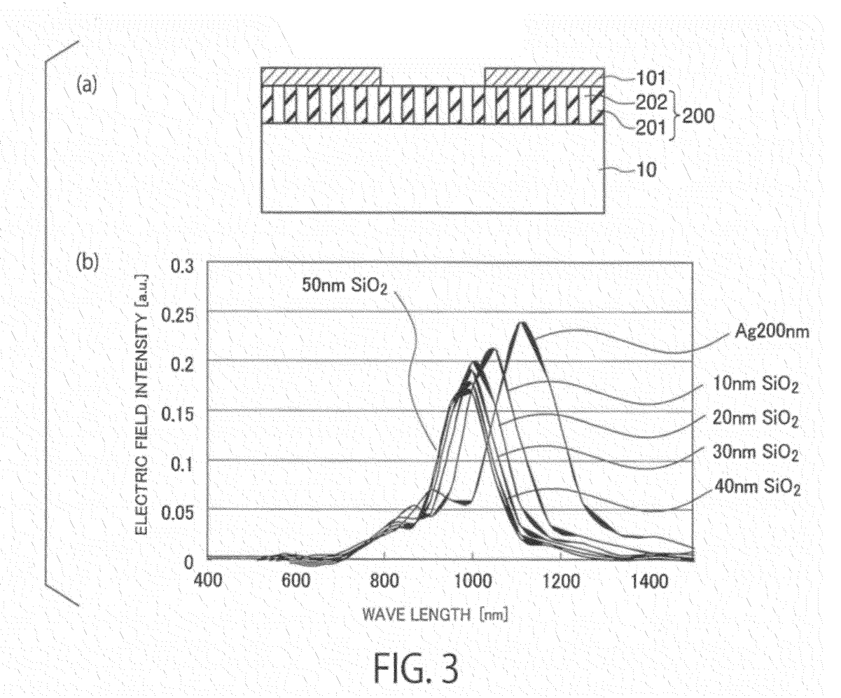

First, as shown in FIG. 3(a), a structure was hypothetically formed by placing a pillar-like SiO₂ structures 201 on a Si layer 10, and forming a mesh 101 made of Ag (30 nm in thickness) on the SiO₂ structures 201. FIG. 3(a) is a cross-sectional view of the structure. The spaces between the SiO₂ structures 201 were filled with air 202. The layer formed by the SiO₂ structures 201 and the air 202 therebetween is referred to as a wavelength converting layer 200. The opening size of the Ag mesh 101 was fixed at 100 nm, and the pitch was fixed at 200 nm. The depth of each SiO₂ structure 201, which is the height of each pillar-like SiO₂ structure 201, was varied in the range of 10 to 50 nm. The largest size of the pillar-like SiO₂ structures 201 in a cross-section perpendicular to the height direction was 10 nm.

Light was emitted from the side of the Ag mesh 101, and the wavelength dependence of the intensity of the electric field generated between the Si layer 10 and the Ag mesh 101 at that point was examined. FIG. 3(b) shows the results of the examination. The abscissa axis indicates the wavelength, and the ordinate axis indicates the absorption spectrum of the Si layer. In a case where the SiO₂ structures 201 do not exist or where the thickness of each SiO₂ structure 201 is 0 nm, the peak of electric field enhancement appears where the wavelength exceeds 1100 nm. It is known that the peak position of electric field enhancement is determined by the Ag mesh 101 or the physicality of the microscopic structures and the refractive index of the dielectric materials existing in the surrounding regions, and a peak appears basically on a longer-wavelength side as the dielectric materials surrounding the microscopic structures are higher. Therefore, if the wavelength converting layer does not exist, the peak of electric field enhancement appears in the longer-wavelength side since the refractive index of Si layer 10 is as big as about four. The SiO₂ structures 201 have a refractive index of 1.45, and the air 202 has a refractive index of 1. Therefore, as the SiO₂ structures 201 become thicker, the peak of electric field enhancement shifts toward shorter wavelengths, as can be seen from FIG. 3(b). As a result, as the thickness of each SiO₂ structure 201 increases from 10 nm to 20 nm, the peak of electric field enhancement shifts to the neighborhood of 1000 nm. Where the thickness of each SiO₂ structure 201 is 30 nm or greater, shifting hardly occurs, and there is almost a saturated state. In view of this, there is a dielectric constant effective from the surface to almost 20 nm. Since the effective dielectric constant of the wavelength converting layer becomes constant at 20 nm or deeper, the peak of electric field enhancement reaches saturation.

Although a case where a material with a low refractive index is used for the pillar-like structures on the wavelength converting layer is described above, dot-like structures or particulate structures may also be used, for example. Alternatively, structures that are stripes when viewed from a direction perpendicular to the stacking direction may be used.

As can be seen from the results, the peak of electric field enhancement can shift where the mean thickness of the SiO₂ structures 201 is as small as 10 nm, and can reach saturation if the mean thickness is 100 nm at a maximum. Since the size of each SiO₂ structure 201 (the largest size in a cross-section perpendicular to the thickness direction) is so small as 10 nm in the above described simulation, the mean refractive index of the air and SiO₂ is regarded as the effective dielectric constant in this structure. The mean size of the microscopic structures should be 100 nm or smaller so that light scattering does not occur.

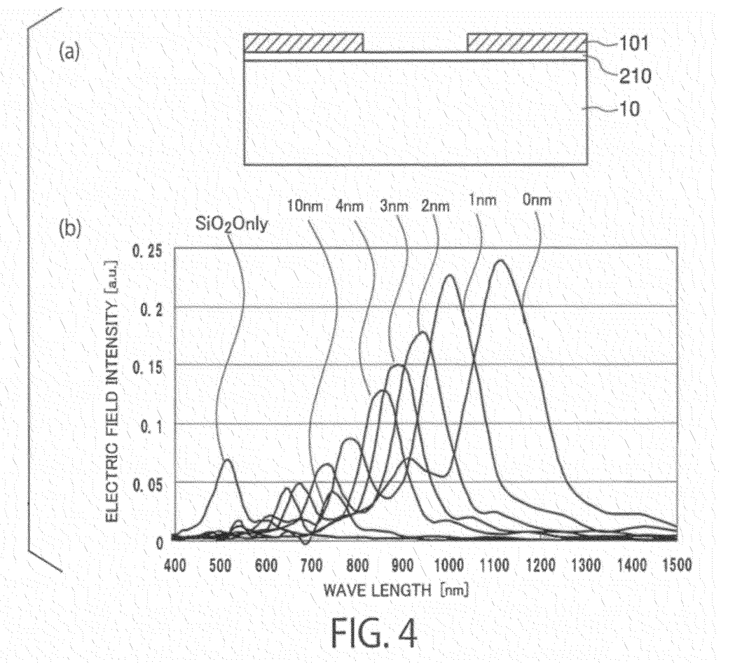

Next, a structure of Si/Ag (30 nm)/air was formed, and a SiO₂ thin film 210 was interposed between a Si layer 10 and a mesh-like Ag mesh 101, as shown in FIG. 4(a). The SiO₂ thin film 210 functions as a wavelength converting layer 200. The opening size of the Ag mesh 101 was fixed at 100 nm, and the pitch was fixed at 200 nm. The thickness of the SiO₂ thin film 210 was varied in the range of 1 nm to 10 nm. Light was emitted from the side of the mesh-like Ag mesh 101, and the wavelength dependence of the intensity of the electric field generated at the interface between Si and Ag at that point was examined. FIG. 4(b) shows the results of the examination. In a case where the SiO₂ thin film 210 does not exist or where the thickness of the SiO₂ thin film 210 is 0 nm, the peak of electric field enhancement appears where the wavelength exceeds 1100 nm as in the above described case. As can be seen from FIG. 4(b), the peak of electric field enhancement shifts toward shorter wavelengths as the thickness of the SiO₂ thin film 210 becomes larger. It has become apparent that the peak of electric field enhancement shifts by 100 nm where the SiO₂ thin film 210 has a film thickness of 1 nm, and the peak can largely shift even if the film thickness is extremely small. Also, the results shown in FIG. 4(b) include the results of a simulation performed where there was no Si layers (there was only SiO₂), and the peak wavelength was 500 nm in that case. That is, if the SiO₂ thin film 210 is made sufficiently large, the peak can shift to 500 nm. However, a photoelectric conversion is not caused unless electric field enhancement occurs in the Si. Therefore, the SiO₂ thin film 210 should be 10 nm or thinner according to the results of the simulation.

As described above, if a material with a lower refractive index than that of the semiconductor layer is provided within a region of at least 5 nm from the end portions of a microscopic structure having local electric fields generated therein, the peak of electric field enhancement can be made to shift toward shorter wavelengths. It should be noted that the “end portions” means the outer rims in a cross-section perpendicular to the stacking direction of the semiconductor layer and the microscopic structure. The local electric fields generated at the interface between Si and Ag are generated from the end portions of Ag, and are distributed within several tens of nanometers from the end portions. Therefore, if a dielectric material with a low refractive index is located too far from the microscopic structure, the local electric fields cannot reach the dielectric material, and loses their effect. To sufficiently move the peak of electric field enhancement by the microscopic structure, each dielectric body should preferably exist within 5 nm from the microscopic structure.

Next, the relationship between the refractive indexes of the microscopic structure and the wavelength converting layer 200 and the peak wavelength of electric field enhancement is described. As described above, to move the peak position of electric field enhancement to the shorter-wavelength side, the refractive indexes of the microscopic structure and the wavelength converting layer should be made lower. In a case where the wavelength converting layer has pillar-like structures (FIG. 3(a)), the shift range can be made wider if the spaces between the pillar-like structures are filled with air (with a refractive index of 1.0). Actually, the refractive index of a semiconductor layer is at least 2.5, and therefore, the peak of electric field enhancement can be made to sufficiently shift toward shorter wavelengths, as long as the refractive index of the pillar-like structures is 2.0 or lower. Meanwhile, the refractive index of the dielectric material with a low refractive index is 1.3. The spaces between the pillar-like structures may be filled with a material with a low refractive index. Examples of materials of the pillar-like structures or materials that can fill the spaces between the pillar-like structures include SiO₂, SiN, SiON, SiO:F, amorphous CF, SiO:CH₃, Al₂O₃, MgO, Y₂O₃, HfO₂, and the like.

Methods of manufacturing the above described photoelectric conversion elements are described. The photoelectric conversion elements described below are solar cells, for example.

First, a method of manufacturing a solar cell having an Ag mesh and SiO₂ microscopic structures as shown in FIG. 3(a) is described. According to this method, the SiO₂ microscopic structures are formed by using a phase separation pattern of a block polymer.

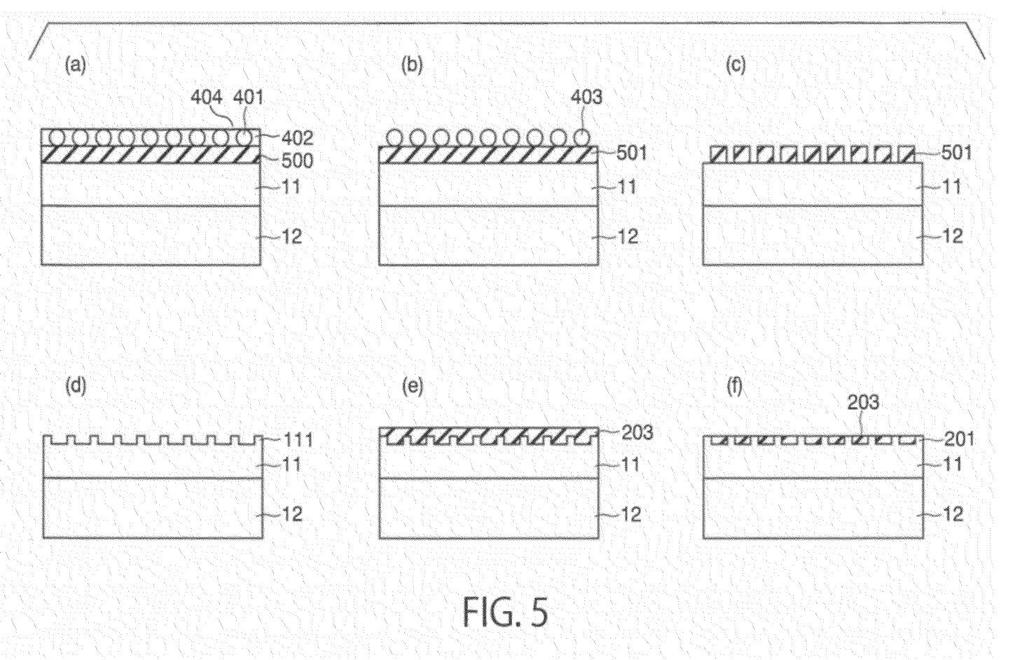

An n⁺-Si layer 11 is first formed on the surface of an n⁻-Si layer 12. A thin film 500 of an organic SOG (Spin-On Glass) composition (OCD-T7 5500-T (a trade name), manufactured by Tokyo Ohka Kogyo Co., Ltd.) is formed on the n⁺-Si layer 11 (FIG. 5(a)).

A block polymer solution having a poly methyl methacrylate PMMA (Mw: 1500) 404 mixed with a block polymer of a polystyrene PS (Mw: 58000) 401 and a PMMA (Mw: 130000) 402 at a weight ratio of 6:4 is spin coated and evaporated to form a thin film.

Annealing is then performed in a nitrogen atmosphere, and a phase separation between the PS 401 and the PMMA 402 is performed to form a dot pattern (FIG. 5(a)).

Through oxygen RIE, etching is selectively performed on the PMMA 402 of the phase-separated PS-PMMA, to form a PS dot pattern 403 (FIG. 5(b)).

With the PS dot pattern 403 using as a mask, a SOG dot pattern 501 is formed by RIE using a fluorine-based gas (FIG. 5(c)).

With the SOG dot pattern 501 using as a mask, a pillar pattern 111 is formed in the n⁺-Si layer 11 by RIE (Reactive Ion Etching) using a chlorine gas (FIG. 5(d)).

A SiO₂ film 203 is then formed by ALD (Atomic Layer Deposition) on the n⁺-Si layer 11 having the pillar pattern 111 formed therein, and the Si pillar pattern 111 is filled with SiO₂ 203 (FIG. 5(e)).

To remove the portions of the SiO₂ film 203 other than the filled portions, etching is performed by RIE using a fluorine-based gas, and the n⁺-Si layer 11 is exposed (FIG. 5(f)). Through the above procedures, the pillar-like SiO₂ microscopic structures 201 are formed in the n⁺-Si layer 11.

An Al layer 1 is formed on the bottom face of the substrate 12 by a vapor deposition technique, and serves as an electrode having an ohmic contact.

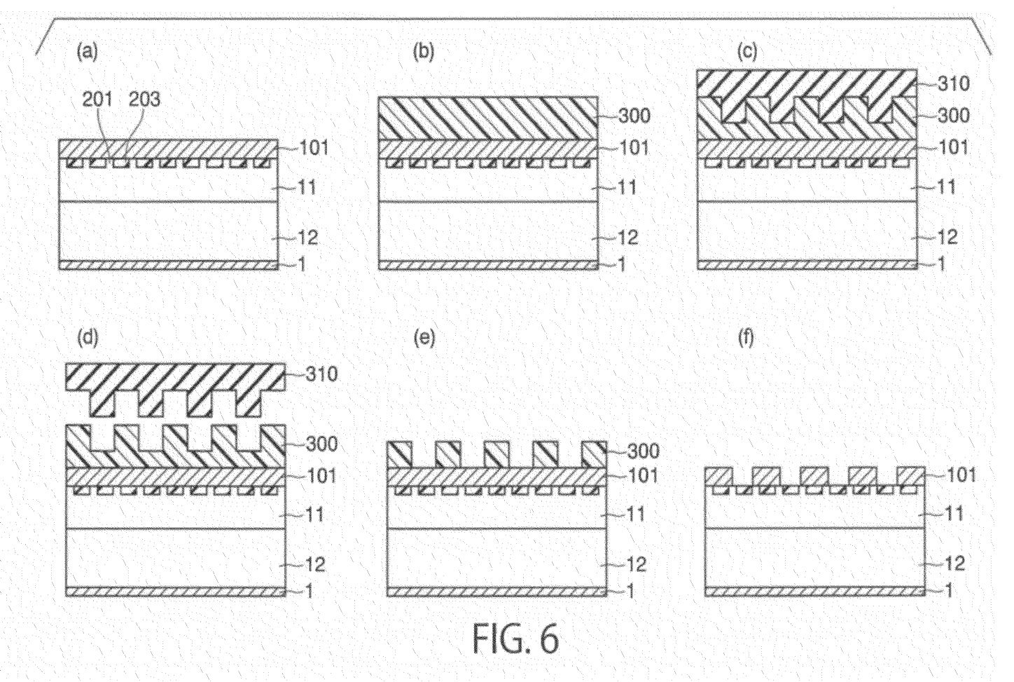

A 30-nm thick Ag layer 101 is then formed on the surfaces of the n⁺-Si layer 11 and the pillar-like SiO₂ microscopic structures 201 (FIG. 6(a)).

A resist 300 is then formed on the Ag layer 101 formed on the substrate surface (FIG. 6(b)). A quartz mold 310 (formed in an area of 9 cm²) having 200-nm convex portions formed thereon is prepared, and imprint is performed by pushing the convex portions of the quartz mold 310 against the resist 300 while the substrate 1 with the resist 300 is being heated (FIG. 6(c)). After the imprint, the substrate 12 is cooled, and the quartz mold is released. After the nanoimprint, concave portions that are 200 nm in size are formed in the resist 300 (FIG. 6(d)).

Etching is then performed on the resist 300 having the concave pattern by RIE using CF₄, and bottom portions of the resist 300 are removed (FIG. 6(e)). After the bottom portions are removed, etching is performed on the Ag layer 101 by an ion milling technique. After the Ag etching, the remaining portions of the resist 300 are removed, and openings are formed in the Ag layer 101 (FIG. 6(f)).

Lastly, a comb-like electrode (not shown) is formed as the surface-side electrode, to complete a solar cell.

The second method concerns a solar cell having a SiO₂ thin film as a wavelength converting layer between an Ag mesh and Si as shown in FIG. 4(a).

To form a metal electrode pattern having 200-nm or smaller openings, a state-of-the-art exposure device or EB (Electron Beam) irradiating device used for semiconductor integrated circuits is required. However, if a state-of-the-art exposure device or EB irradiating device is used, forming a metal electrode pattern with a large area at a low cost is considered impossible. One of the methods of forming a large-area metal electrode pattern at a low cost involves nanoimprint. The method of forming a nano-mesh electrode through nanoimprint is described below.

As a substrate, a p-type Si substrate 12 having a doping concentration of 10¹⁶ cm⁻³ is prepared. The surface of the p-type Si substrate 12 is doped with P by thermal diffusion, and a pn junction is formed at a surface concentration of 10²⁰ cm⁻³. That is, an n-type Si layer 11 is formed on the p-type Si layer 12.

A 2-nm thick SiO₂ film 200 is then formed on the n-type Si layer 11 by a thermal oxidation technique.

An Al layer 1 is then formed on the bottom face of the p-type Si substrate 12 by a vapor deposition technique to form an electrode having an ohmic contact.

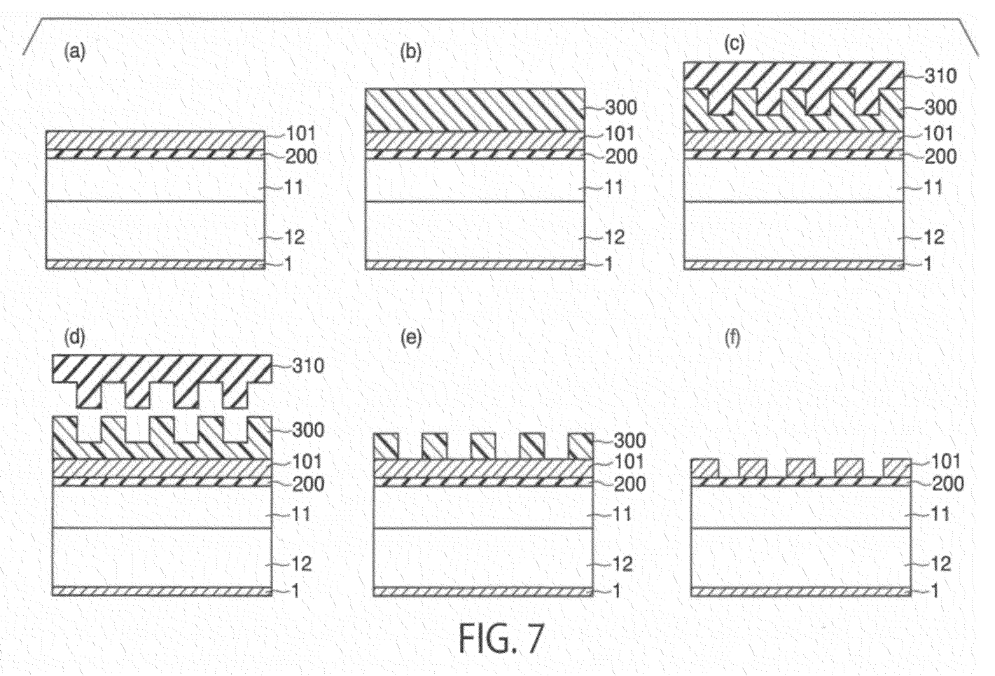

A 30-nm thick Ag layer 101 is then formed on the substrate surface (FIG. 7(a)).

A resist 300 is then formed on the Ag layer 101 formed on the substrate surface (FIG. 7(b)). A quartz mold 310 (formed in an area of 9 cm²) having 200-nm convex portions formed thereon is prepared, and imprint is performed by pushing the convex portions of the quartz mold 310 against the resist 300 while the substrate 1 with the resist 300 is being heated (FIG. 7(c)). After the imprint, the substrate 12 is cooled, and the quartz mold is released. After the nanoimprint, concave portions that are 200 nm in size are formed in the resist 300 (FIG. 7(d)).

Etching is then performed on the resist 300 having the concave pattern by RIE using CF₄, and bottom portions or the resist 300 are removed (FIG. 7(e)). After the bottom portions are removed, etching is performed on the Ag layer 101 by an ion milling technique. After the Ag etching, the remaining portions of the resist 300 are removed, and openings are formed in the Ag layer 101 (FIG. 7(f)).

Lastly, a comb-like electrode (not shown) is formed as the surface-side electrode to complete a solar cell.

Through the above process, a solar cell having the nano-mesh metal 101 and the SiO₂ thin film 200 is completed.

Also, with a compound semiconductor, a solar cell having a nano-mesh metal can be formed by the same process as above. Examples of compound semiconductors include GaAs, CdTe, CIS-based materials, and the like.

It should be noted that the refractive index of each material is a value measured by a spectroscopic ellipsometer. The shape of each microscopic structure becomes apparent through SEM (Scanning Electron Microscope) observation, and the material of each microscopic structure becomes apparent through composition analysis by SIMS (Secondary Ion Mass Spectrometry), XPS (X-ray Photoelectron Spectroscopy), or the like. The refractive index of each wavelength converting layer is measured by examining the relationship between reflectivity and wavelength with a spectroscopic ellipsometer for microscopic structures, wavelength converting layers, and semiconductor layers. If a wavelength converting layer is formed by stripe structures, dot-like structures, or pillar-like structures, the mean size (the largest size) and the mean thickness of the structures are determined by analyzing cross-sectional SEM images. The difference between the portion closest to the metal electrode side and the portion farthest from the metal electrode side in each structure formed in the photoelectric conversion element set as a thickness, and the mean thickness is the average value of the thicknesses. The mean width in each structure formed in the photoelectric conversion element is set as a size, and the mean size is the average value of the mean widths of the structure. There are cases where native oxide film exists in the surface of the semiconductor layer, and the above principle can also be applied to cases where the native oxide film is formed.

The embodiments are now described in greater detail by way of examples. Solar cells each having a size of 9 cm² were manufactured, and the characteristics were evaluated. In each of the following examples, the method of forming a nano-mesh involves a nanoimprint technique. However, a nano-mesh can also be formed by some other method, such as a method utilizing self-organization.

### Example 1

### Nano-Mesh+SiO₂ Thin Film

A p-type Si substrate having a doping concentration of 10¹⁶ cm⁻³ was prepared. The surface of the p-type Si substrate 12 was doped with P by thermal diffusion, and a p-n⁺ junction was formed at 10²⁰ cm⁻³.

A 2-nm thick SiO₂ film 200 was then formed on the n⁺-type Si layer 11 by a thermal oxidation technique.

A 100-nm thick Al layer 1 was then formed on the bottom face of the substrate 12 by a vapor deposition technique to form an electrode having an ohmic contact in the bottom face thereof. A 30-nm thick Ag layer 101 was formed above the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Ag layer 101 formed on the substrate surface at 2000 rpm for 30 seconds, and was then heated on a hot plate at 110° C. for 90 seconds to evaporate the solvent (FIG. 7(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold against the resist 300 with a pressure of 10 MPa while the substrate 12 with the resist 300 was being heated at 120° C. (FIG. 7(c)). After the imprint, the substrate 12 was cooled to room temperature, and the quartz mold 310 was released (FIG. 7(d)). After the imprint, concave portions that were arranged at a pitch of 200 nm, were 100 nm in size, and were 100 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist 300 were removed, and the Ag layer 101 was exposed (FIG. 7(e)). With the use of an ion milling device, 80-second etching was performed on the Ag layer 101 at an accelerating voltage of 500 V and with an ion current of 40 mA, to form a metal electrode layer 101 having openings. Through the ion milling, a pattern with openings that were arranged at a pitch of 200 nm and were 100 nm in size was formed in the Ag layer. The remaining portions of the resist were removed by an organic solvent.

A surface electrode was formed by manufacturing a comb-like electrode by a screen printing technique using an Ag paste including an epoxy-based thermosetting resin. In this manner, a Si solar cell having a nano-mesh electrode was completed (FIG. 7(f)).

For comparison, an Si solar cell that had a nano-mesh metal but did not have a SiO₂ film 200 was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with a 2-nm SiO₂ film 200 and a nano-mesh metal 101 had a preferred value of 10.5%. On the other hand, the photoelectric conversion efficiency of the Si solar cell that had a nano-mesh metal but did not have a SiO₂ film was 9.5%.

As can be seen from the results, the photoelectric conversion efficiency became higher as the peak wavelength of electric field enhancement shifted toward the shorter-wavelength side by virtue of the insertion of a SiO₂ film.

### Example 2

### Nano-Mesh+SiO₂ Thin Film

The same p-type Si substrate 12 as that of Example 1 was prepared. The surface of the p-type Si substrate 12 was doped with P by thermal diffusion, and a p-n⁺ junction was formed at 10²⁰ cm⁻³.

A 2-nm thick SiO₂ film 200 was then formed on the n⁺-type Si layer 11 by a thermal oxidation technique.

A 100-nm thick Al layer 1 was then formed on the bottom face of the substrate 12 by a vapor deposition technique to form an electrode having an ohmic contact in the bottom face thereof. A 30-nm thick Au layer 101 was formed above the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Au layer 101 formed on the substrate surface at 2000 rpm for 30 seconds, and was then heated on a hot plate at 110° C. for 90 seconds, to evaporate the solvent (FIG. 7(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist with a pressure of 10 MPa while the substrate 12 with the resist 300 was being heated at 120° C. (FIG. 7(c)). After the imprint, the substrate 12 was cooled to room temperature, and the quartz mold 310 was released (FIG. 7(d)). After the imprint, concave portions that were arranged at a pitch of 200 nm, were 100 nm in size, and were 100 nm in depth were formed in the resist.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist 300 were removed, and the Au layer 101 was exposed (FIG. 7(e)).

With the use of an ion milling device, the Au layer 101 was etched by the ion milling for 90 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Au layer 101. The remaining portions of the resist were removed by an organic solvent.

A surface electrode 101 was formed by manufacturing a comb-like electrode by a screen printing technique using an Ag paste including an epoxy-based thermosetting resin. In this manner, a Si solar cell having a nano-mesh electrode was completed (FIG. 7(f)).

For comparison, an Si solar cell that had a nano-mesh metal but did not have a SiO₂ film 200 was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with a 2-nm SiO₂ film 200 and a nano-mesh metal 101 had a preferred value of 10.4%. On the other hand, the photoelectric conversion efficiency of the Si solar cell that had a nano-mesh metal but did not have a SiO₂ film was 9.5%.

As can be seen from the results, the photoelectric conversion efficiency became higher as the peak wavelength of electric field enhancement shifted toward the shorter-wavelength side by virtue of the insertion of a SiO₂ film.

### Example 3

### Nano-Mesh+SiO₂ Thin Film

The same p-type Si substrate as that of Example 1 was prepared. The surface of the p-type Si substrate 12 was doped with P by thermal diffusion, and a p-n⁺ junction was formed at 10²⁰ cm⁻³.

A 2-nm thick SiO₂ film 200 was then formed on the n⁺-type Si layer 11 by a thermal oxidation technique.

A 100-nm thick Al layer 1 was then formed on the bottom face of the substrate by a vapor deposition technique to form an electrode having an ohmic contact in the bottom face thereof. A 30-nm thick Al layer 101 was formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Al layer 101 formed above the substrate surface at 2000 rpm for 30 seconds, and was then heated on a hot plate at 110° C. for 90 seconds to evaporate the solvent (FIG. 7(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold against the resist 300 with a pressure of 10 MPa while the substrate with the resist 300 was being heated at 120° C. (FIG. 7(c)). After the imprint, the substrate was cooled to room temperature, and the quartz mold 310 was released (FIG. 7(d)). After the imprint, concave portions that were arranged at a pitch of 200 nm, were 100 nm in size, and were 100 nm in depth were formed in the resist.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist 300 were removed, and the Al layer 101 was exposed (FIG. 7(e)).

The Al layer 101 was etched by RIE for 60 seconds at a Cl₂ flow rate of 15 sccm, at an Ar flow rate of 15 sccm, and with an RF power of 100 W. Through the RIE using a chlorine-based gas, a pattern with openings that were arranged at a pitch of 200 nm and were 100 nm in size was formed in the Al layer 101. The remaining portions of the resist 300 were removed by oxygen ashing.

A surface electrode was formed by manufacturing a comb-like electrode by a screen printing technique using an Ag paste including an epoxy-based thermosetting resin. In this manner, a Si solar cell having a nano-mesh electrode was completed (FIG. 7(f)).

For comparison, an Si solar cell that had a nano-mesh metal but did not have a SiO₂ film 200 was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with a 2-nm SiO₂ film 200 and a nano-mesh metal had a preferred value of 10.2%. On the other hand, the photoelectric conversion efficiency of the Si solar cell that had a nano-mesh metal but did not have a SiO₂ film was 9.5%.

As can be seen from the results, the photoelectric conversion efficiency became higher as the peak wavelength of electric field enhancement shifted toward the shorter-wavelength side by virtue of the insertion of a SiO₂ film.

### Example 4

### Nano-Mesh+SiN Thin Film

The same p-type Si substrate 12 as that of Example 1 was prepared. The surface of the p-type Si substrate 12 was doped with P by thermal diffusion, and a p-n⁺ junction was formed at 10²⁰ cm⁻³.

A 4-nm thick SiN film 200 was then formed on the n⁺-type Si layer 11 by a thermal oxidation technique.

A 100-nm thick Al layer 1 was then formed on the bottom face of the substrate 12 by a vapor deposition technique to form an electrode having an ohmic contact in the bottom face thereof. A 30-nm thick Ag layer 101 was formed above the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Ag layer 101 formed on the substrate surface at 2000 rpm for 30 seconds, and was then heated on a hot plate at 110° C. for 90 seconds to evaporate the solvent (FIG. 7(b)). The film thickness of the resist was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist 300 was being heated at 120° C. (FIG. 7(c)). After the imprint, the substrate was cooled to room temperature, and the quartz mold 310 was released (FIG. 7(d)). After the imprint, concave portions that were arranged at a pitch of 200 nm, were 100 nm in size, and were 100 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist 300 were removed, and the Ag layer 101 was exposed (FIG. 7(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a Si solar cell having a nano-mesh electrode was completed (FIG. 7(f)).

For comparison, an Si solar cell that had a nano-mesh metal but did not have a SiN film 200 was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with a 4-nm SiN film 200 and a nano-mesh metal had a preferred value of 11.0%. On the other hand, the photoelectric conversion efficiency of the Si solar cell that had a nano-mesh metal but did not have a SiN film 200 was 9.5%.

As can be seen from the results, the photoelectric conversion efficiency became higher as the peak wavelength of electric field enhancement shifted toward the shorter-wavelength side by virtue of the insertion of a SiN film.

### Example 5

### Nano-Mesh+SiON Thin Film

The same p-type Si substrate 12 as that of Example 1 was prepared. The surface of the p-type Si substrate 12 was doped with P by thermal diffusion, and a p-n⁺ junction was formed at 10²⁰ cm⁻³

A 3-nm thick SiON film 200 was then formed on the n⁺-type Si layer 11 by CVD method.

A 100-nm thick Al layer 1 was then formed on the bottom face of the substrate by a vapor deposition technique to form an electrode having an ohmic contact in the bottom face thereof. A 30-nm thick Ag layer 101 was formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 2000 rpm for 30 seconds, and was then heated on a hot plate at 110° C. for 90 seconds to evaporate the solvent (FIG. 7(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold against the resist with a pressure of 10 MPa while the substrate with the resist was being heated at 120° C. (FIG. 7(c)). After the imprint, the substrate was cooled to room temperature, and the quartz mold was released (FIG. 7(d)). After the imprint, concave portions that were arranged at a pitch of 200 nm, were 100 nm in size, and were 100 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist 300 were removed, and the Ag layer 101 was exposed (FIG. 7(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a Si solar cell having a nano-mesh electrode was completed (FIG. 7(f)).

For comparison, an Si solar cell that had a nano-mesh metal but did not have a SiON film 200 was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with a 3-nm SiON film 200 and a nano-mesh metal had a preferred value of 10.8%. On the other hand, the photoelectric conversion efficiency of the Si solar cell that had a nano-mesh metal but did not have a SiON film 200 was 9.5%.

As can be seen from the results, the photoelectric conversion efficiency became higher as the peak wavelength of electric field enhancement shifted toward the shorter-wavelength side by virtue of the insertion of a SiON film.

### Example 6

### Nano-Mesh+SiO:F Thin Film

The same p-type Si substrate 12 as that of Example 1 was prepared. The surface of the p-type Si substrate was doped with P by thermal diffusion, and a p-n⁺ junction was formed at 10²⁰ cm⁻³.

A 5-nm thick SiO:F film 200 was then formed on the n⁺-type Si layer by CVD method.

A 100-nm thick Al layer 1 was then formed on the bottom face of the substrate by a vapor deposition technique to form an electrode having an ohmic contact in the bottom face thereof. A 30-nm thick Ag layer 101 was formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Ag layer 101 formed on the substrate surface at 2000 rpm for 30 seconds, and was then heated on a hot plate at 110° C. for 90 seconds, to evaporate the solvent (FIG. 7(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist was being heated at 120° C. (FIG. 7(c)). After the imprint, the substrate was cooled to room temperature, and the quartz mold 310 was released (FIG. 7(d)). After the imprint, concave portions that were arranged at a pitch of 200 nm, were 100 nm in size, and were 100 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist 300 were removed, and the Ag layer 101 was exposed (FIG. 7(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a Si solar cell having a nano-mesh electrode was completed (FIG. 7(f)).

For comparison, an Si solar cell that had a nano-mesh metal but did not have a SiO:F film 200 was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with a 5-nm SiO:F film 200 and a nano-mesh metal had a preferred value of 11.3%. On the other hand, the photoelectric conversion efficiency of the Si solar cell that had a nano-mesh metal but did not have a SiO:F film 200 was 9.5%.

As can be seen from the results, the photoelectric conversion efficiency became higher as the peak wavelength of electric field enhancement shifted toward the shorter-wavelength side by virtue of the insertion of a SiO:F film.

### Example 7

### Nano-Mesh+SiO₂ Structures

The same p-type Si substrate 12 as that of Example 1 was prepared. The surface of the p-type Si substrate 12 was doped with P by thermal diffusion, and a p-n⁺ junction was formed at 10²⁰ cm⁻³.

A solution formed by diluting an organic SOG composition (OCD-T7 5500-T (a trade name), manufactured by Tokyo Ohka Kogyo Co., Ltd.) with EL at 1:1 was spin-coated on the n⁺-type Si layer 11 at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG 500. The film thickness after the hardening was 50 nm.

A solution formed by dissolving 2 wt % of a polymer having a PMMA (Mw: 1500) mixed with a block polymer of a PS (Mw: 58000) and a PMMA (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 80 nm.

The film was annealed for 4 hours at 210° C. in a nitrogen atmosphere, and a phase separation between the PS and the PMMA was performed to form a polystyrene dot pattern of approximately 70 nm in diameter (FIG. 5(a)). After that, the film was etched by RIE at an O₂ flow rate of 30 sccm, at a pressure of 13.3 Pa (100 mTorr), and with a power of 100 W for 15 seconds. Through the RIE, the PMMA of the phase-separated PS-PMMA was selectively removed to form a PS dot pattern (FIG. 5(b)).

With the PS dot pattern using as a mask, a SOG dot pattern was formed by RIE for 90 seconds at a CF₄ flow rate of 30 sccm, at a pressure of 1.33 Pa (10 mTorr), and with a power of 100 W (FIG. 5(c)).

With the SOG dot pattern using as a mask, Si was etched by RIE at a Cl₂ flow rate of 15 sccm, at an Ar flow rate of 15 sccm, and with an RF power of 100 W for 60 seconds. After the RIE using the chlorine gas, a pillar pattern that was 40 nm in size and was 50 nm in height was formed in the n⁺-type Si layer (FIG. 5(d)).

A SiO₂ film was then formed by ALD (Atomic Layer Deposition) method on the n⁺-Si layer having the pillar pattern formed therein, and the Si pillar pattern was filled with SiO₂ (FIG. 5(e)).

To remove the SiO₂ portions formed on the filled n⁺-type Si layer, the SiO₂ was etched by RIE for 30 seconds at a CF₄ flow rate of 30 sccm, at a pressure of 1.33 Pa (10 mTorr), and with a power of 100 W, and the n⁺-type Si layer was exposed. Through the above procedures, SiO₂ microscopic structures were formed in the n⁺-Si layer (FIG. 5(f)).

A 100-nm thick Al layer 1 was formed on the bottom face of the substrate by a vapor deposition technique to form an electrode having an ohmic contact in the bottom face thereof. A 30-nm thick Ag layer 101 was then formed on the substrate surface by a vapor deposition technique (FIG. 6(a)).

A solution formed by diluting a resist (THMR IP3250, manufactured by Tokyo Ohka Kogyo Co., Ltd.) with ethyl lactate (EL) at 1:2 was spin-coated on the AG layer 101 formed on the substrate surface at 2000 rpm for 30 seconds, and was then heated on a hot plate at 110° C. for 90 seconds to evaporate the solvent (FIG. 6(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold against the resist with a pressure of 10 MPa while the substrate with the resist was being heated at 120° C. (FIG. 6(c)). After the imprint, the substrate was cooled to room temperature, and the quartz mold 310 was released (FIG. 6(d)). After the imprint, concave portions that were arranged at a pitch of 200 nm, were 100 nm in size, and were 100 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist 300 were removed, and the Ag layer 101 was exposed (FIG. 6(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a Si solar cell having a nano-mesh electrode was completed (FIG. 6(f)).

For comparison, an Si solar cell that had a nano-mesh metal but did not have an SiO₂ microscopic structures was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with an SiO₂ microscopic structures and a nano-mesh metal had a preferred value of 10.2%. On the other hand, the photoelectric conversion efficiency of the Si solar cell that had a nano-mesh metal but did not have an SiO₂ microscopic structures was 9.5%.

As can be seen from the results, the photoelectric conversion efficiency became higher as the peak wavelength of electric field enhancement shifted toward the shorter-wavelength side by virtue of the insertion of an SiO₂ microscopic structures.

### Example 8

### Nano-Mesh+Al₂O₃ Structures

The same p-type Si substrate 12 as that of Example 1 was prepared. The surface of the p-type Si substrate 12 was doped with P by thermal diffusion, and a p-n⁺ junction was formed at 10²⁰ cm⁻³.

A solution formed by diluting an organic SOG composition (OCD-T7 5500-T (a trade name), manufactured by Tokyo Ohka Kogyo Co., Ltd.) with EL at 1:1 was spin-coated on the n⁺-type Si layer 11 at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG 500. The film thickness after the hardening was 50 nm.

A solution formed by dissolving 2 wt % of a polymer having a PS (Mw: 1800) mixed with a block polymer of a PS (Mw: 120000) and a PMMA (Mw: 45000) at a weight ratio of 8:2 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 70 nm.

The film was annealed for 4 hours at 210° C. in a nitrogen atmosphere, and a phase separation between the PS and the PMMA was performed to form a polystyrene hole pattern of approximately 60 nm in diameter (FIG. 5(a)).

After that, the film was etched by RIE at an O₂ flow rate of 30 sccm, at a pressure of 13.3 Pa (100 mTorr), and with a power of 100 W for 12 seconds. Through the RIE, the PMMA of the phase-separated PS-PMMA was selectively removed to form a PS hole pattern (FIG. 5(b)).

With the PS dot pattern using as a mask, a SOG hole pattern was formed by RIE for 90 seconds at a CF₄ flow rate of 30 sccm, at a pressure of 1.33 Pa (10 mTorr), and with a power of 100 W (FIG. 5(c)).

With the SOG hole pattern using as a mask, Si was etched by RIE at a Cl₂ flow rate of 15 sccm, at an Ar flow rate of 15 sccm, and with an RF power of 100 W for 60 seconds. After the RIE using the chlorine gas, a hole pattern that was 35 nm in size and was 40 nm in height was formed in the n⁺-type Si layer (FIG. 5(d)).

An Al₂O₃ film 203 was then formed by ALD method on the n⁺-Si layer 11 having the hole pattern formed therein, and the Si hole pattern was filled with Al₂O₃ (FIG. 5(e)).

To remove the Al₂O₃ portions formed on the filled n⁺-Si layer, the Al₂O₃ was etched by RIE for 30 seconds at a Cl₂ flow rate of 15 sccm, at an Ar flow rate of 15 sccm, and with an RF power of 100 W, and the n⁺-type Si layer was exposed (FIG. 5(f)). Through the above procedures, Al₂O₃ microscopic structures were formed in the n⁺-type Si layer.

A 100-nm thick Al layer 1 was then formed on the bottom face of the substrate by a vapor deposition technique to form an electrode having an ohmic contact in the bottom face thereof. A 30-nm thick Ag layer 101 was then formed on the substrate surface by a vapor deposition technique (FIG. 6(a)).

A solution formed by diluting a resist (THMR IP3250, manufactured by Tokyo Ohka Kogyo Co., Ltd.) with ethyl lactate (EL) at 1:2 was spin-coated on the Ag layer 101 formed on the substrate surface at 2000 rpm for 30 seconds, and was then heated on a hot plate at 110° C. for 90 seconds to evaporate the solvent (FIG. 6(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist was being heated at 120° C. (FIG. 6(c)). After the imprint, the substrate was cooled to room temperature, and the quartz mold 310 was released (FIG. 6(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist 300 were removed, and the Ag layer 101 was exposed (FIG. 6(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a Si solar cell having a nano-mesh electrode was completed (FIG. 6(f)).

For comparison, an Si solar cell that had a nano-mesh metal but did not have an Al₂O₃ microscopic structures was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with an Al₂O₃ microscopic structures and a nano-mesh metal had a preferred value of 10.5%. On the other hand, the photoelectric conversion efficiency of the Si solar cell that had a nano-mesh metal but did not have an Al₂O₃ microscopic structures was 9.5%.

### Example 9

### Nano-Mesh+SiN Structures

The same p-type Si substrate 12 as that of Example 1 was prepared. The surface of the p-type Si substrate 12 was doped with P by thermal diffusion, and a p-n⁺ junction was formed at 10²⁰ cm⁻³.

A solution formed by diluting an organic SOG composition (OCD-T7 5500-T (a trade name), manufactured by Tokyo Ohka Kogyo Co., Ltd.) with EL at 1:1 was spin-coated on the n⁺-type Si layer 11 at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG 500. The film thickness after the hardening was 50 nm.

A solution formed by dissolving 2 wt % of a polymer having a PS (Mw: 1800) mixed with a block polymer of a PS (Mw: 120000) and a PMMA (Mw: 45000) at a weight ratio of 8:2 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 70 nm.

The film was annealed for 4 hours at 210° C. in a nitrogen atmosphere, and a phase separation between the PS and the PMMA was performed to form a polystyrene hole pattern of approximately 60 nm in diameter (FIG. 5(a)).

After that, the film was etched by RIE for 12 seconds at an O₂ flow rate of 30 sccm, at a pressure of 13.3 Pa (100 mTorr), and with a power of 100 W. Through the RIE, the PMMA of the phase-separated PS-PMMA was selectively removed to form a PS hole pattern (FIG. 5(b)).

With the PS dot pattern using as a mask, a SOG hole pattern was formed by performing 90-second etching at a CF₄ flow rate of 30 sccm, at a pressure of 1.33 Pa (10 mTorr), and with a power of 100 W (FIG. 5(c)).

With the SOG hole pattern using as a mask, Si was etched by RIE at a Cl₂ flow rate of 15 sccm, at an Ar flow rate of 15 sccm, and with an RF power of 100 W for 60 seconds. After the RIE using the chlorine gas, a hole pattern that was 35 nm in size and was 40 nm in height was formed in the n⁺-Si layer 11 (FIG. 5(d)).

A SiN film 203 was then formed by ALD method on the n⁺-Si layer 11 having the hole pattern formed therein, and the Si hole pattern was filled with SiN (FIG. 5(e)).

To remove the SiN portions formed on the filled n⁺-type Si layer, the SiN was etched by RIE for 30 seconds at a CF₄ flow rate of 30 sccm, at a pressure of 1.33 Pa (10 mTorr), and with a power of 100 W, and the n⁺-type Si layer was exposed. Through the above procedures, SiN microscopic structures were formed in the n⁺-type Si layer (FIG. 5(f)).

A 100-nm thick Al layer 1 was then formed on the bottom face of the substrate by a vapor deposition technique to form an electrode having an ohmic contact in the bottom face thereof. A 30-nm thick Ag layer 101 was then formed on the substrate surface by a vapor deposition technique (FIG. 6(a)).

A solution formed by diluting a resist (THMR IP3250, manufactured by Tokyo Ohka Kogyo Co., Ltd.) with ethyl lactate (EL) at 1:2 was spin-coated on the Ag layer 101 formed on the substrate surface at 2000 rpm for 30 seconds, and was then heated on a hot plate at 110° C. for 90 seconds to evaporate the solvent (FIG. 6(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist 300 was being heated at 120° C. (FIG. 6(c)). After the imprint, the substrate was cooled to room temperature, and the quartz mold 310 was released (FIG. 6(d)). After the imprint, concave portions that were arranged at a pitch of 200 nm, were 100 nm in size, and were 100 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist 300 were removed, and the Ag layer 101 was exposed (FIG. 6(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a Si solar cell having a nano-mesh electrode was completed (FIG. 6(f)).

For comparison, an Si solar cell that had a nano-mesh metal but did not have an SiN microscopic structures was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with an SiN microscopic structures and a nano-mesh metal had a preferred value of 10.3%. On the other hand, the photoelectric conversion efficiency of the Si solar cell that had a nano-mesh metal but did not have an SiN microscopic structures was 9.5%.

### Example 10

### Dots+SiO₂ Thin Film

In this example, microscopic structures are miniature structures scattered in a plane perpendicular to the stacking direction are arranged in a dot pattern. In a cross-section structure, metal members are arranged at intervals, like a mesh-like microscopic structure. Therefore, this example is described with reference to FIGS. 7(a) to 7(f).

A p-type Si substrate 12 having a doping concentration of 10¹⁶ cm⁻³ was prepared. The surface of the p-type Si substrate 12 was doped with P by thermal diffusion, and a p-n⁺ junction was formed at 10²⁰ cm⁻³.

A 3-nm thick SiO₂ film 200 was then formed on the n⁺-type Si layer 11 by a thermal oxidation technique.

A 100-nm thick Al layer 1 was then formed on the bottom face of the substrate by a vapor deposition technique to form an electrode having an ohmic contact in the bottom face thereof. A 30-nm thick Au layer 101 was formed above the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Au layer 101 formed on the substrate surface at 3000 rpm for 30 seconds, and was then heated on a hot plate at 110° C. for 90 seconds to evaporate the solvent (FIG. 7(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 7(c)). After the imprint, the substrate was cooled to room temperature, and the quartz mold 310 was released (FIG. 7(d)). After the imprint, concave portions that were arranged in a dot pattern, were 60 nm in size, and were 70 nm in depth were formed in the resist 300.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist 300 were removed, and the Au layer 101 was exposed (FIG. 7(e)).

With the use of an ion milling device, the Au layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, a Si solar cell having dots was completed (FIG. 7(f)).

For comparison, an Si solar cell that had dots but did not have an SiO₂ film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with a 3-nm SiO₂ film and a nano-mesh metal 101 had a preferred value of 11.5%. On the other hand, the photoelectric conversion efficiency of the Si solar cell that had dots but did not have an SiO₂ film was 10.0%.

### Example 11

### Dots+SiN Thin Film

A p-type Si substrate 12 having a doping concentration of 10¹⁶ cm⁻³ was prepared. The surface of the p-type Si substrate was doped with P by thermal diffusion, and a p-n⁺ junction was formed at 10²⁰ cm⁻³.

A 5-nm thick SiN film 200 was then formed on the n⁺-type Si layer 11 by a thermal oxidation technique.

A 100-nm thick Al layer 1 was then formed on the bottom face of the substrate by a vapor deposition technique to form an electrode having an ohmic contact in the bottom face thereof. A 30-nm thick Al layer 101 was formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Al layer formed on the substrate surface at 3000 rpm for 30 seconds, and was then heated on a hot plate at 110° C. for 90 seconds to evaporate the solvent (FIG. 7(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 7(c)). After the imprint, the substrate was cooled to room temperature, and the quartz mold 310 was released (FIG. 7(d)). After the imprint, concave portions that were arranged in a dot pattern, were 60 nm in size, and were 70 nm in depth were formed in the resist.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist 300 were removed, and the Al layer 101 was exposed (FIG. 7(e)).

With the use of an ion milling device, the Al layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Al layer 101. The remaining portions of the resist were removed with an organic solvent.

A surface electrode was formed by manufacturing a comb-like electrode by a screen printing technique using an Ag paste including an epoxy-based thermosetting resin. In this manner, a Si solar cell having dots was completed (FIG. 7(f)).

For comparison, an Si solar cell that had dots but did not have an SiN film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with a 5-nm SiN film and dots had a preferred value of 11.3%. On the other hand, the photoelectric conversion efficiency of the Si solar cell that had dots but did not have an SiN film was 10.1%.

### Example 12

### Dots+SiO₂ Structures

The same p-type Si substrate 12 as that of Example 1 was prepared. The surface of the p-type Si substrate 12 was doped with P by thermal diffusion, and a p-n⁺ junction was formed at 10²⁰ cm⁻³.

A solution formed by diluting an organic SOG composition (OCD-T7 5500-T (a trade name), manufactured by Tokyo Ohka Kogyo Co., Ltd.) with EL at 1:1 was spin-coated on the n⁺-type Si layer 11 at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG 500. The film thickness after the hardening was 50 nm.

A solution formed by dissolving 2 wt % of a polymer having a PMMA (Mw: 1500) mixed with a block polymer of a PS (Mw: 58000) and a PMMA (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 80 nm.

The film was annealed for 4 hours at 210° C. in a nitrogen atmosphere, and a phase separation between the PS and the PMMA was performed to form a polystyrene dot pattern of approximately 70 nm in diameter (FIG. 5(a)).

After that, the film was etched by RIE for 15 seconds at an O₂ flow rate of 30 sccm, at a pressure of 13.3 Pa (100 mTorr), and with a power of 100 W. Through the RIE, the PMMA of the phase-separated PS-PMMA was selectively removed to form a PS dot pattern (FIG. 5(b)).

With the PS dot pattern using as a mask, a SOG dot pattern was formed by RIE for 90 seconds at a CF₄ flow rate of 30 sccm, at a pressure of 1.33 Pa (10 mTorr), and with a power of 100 W (FIG. 5(c)).

With the SOG dot pattern using as a mask, Si was etched by RIE for 60 seconds at a Cl₂ flow rate of 15 sccm, at an Ar flow rate of 15 sccm, and with an RF power of 100 W. After the RIE using the chlorine gas, a pillar pattern that was 40 nm in size and was 50 nm in height was formed in the n⁺-type Si layer (FIG. 5(d)).

A SiO₂ film was then formed by ALD method on the n⁺-Si layer having the pillar pattern formed therein, and the Si pillar pattern was filled with SiO₂ (FIG. 5(e)).

To remove the SiO₂ portions formed on the filled n⁺-Si layer, the SiO₂ was etched by RIE for 30 seconds at a CF₄ flow rate of 30 sccm, at a pressure of 1.33 Pa (10 mTorr), and with a power of 100 W, and the n⁺-type Si layer was exposed. Through the above procedures, SiO₂ microscopic structures were formed in the n⁺-Si layer 11 (FIG. 5(f)).

A 100-nm thick Al layer 1 was formed under the bottom face of the substrate by a vapor deposition technique to form an electrode having an ohmic contact in the bottom face thereof. A 30-nm thick Au layer 101 was then formed on the substrate surface by a vapor deposition technique (FIG. 6(a)).

A solution formed by diluting a resist (THMR IP3250, manufactured by Tokyo Ohka Kogyo Co., Ltd.) with ethyl lactate (EL) at 1:2 was spin-coated on the Au layer 101 formed on the substrate surface at 3000 rpm for 30 seconds, and was then heated on a hot plate at 110° C. for 90 seconds to evaporate the solvent (FIG. 6(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 6(c)). After the imprint, the substrate was cooled to room temperature, and the quartz mold 310 was released (FIG. 6(d)). After the imprint, concave portions that were arranged in a dot pattern, were 60 nm in size, and were 70 nm in depth were formed in the resist 300.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist 300 were removed, and the Au layer 101 was exposed (FIG. 7(e)).

With the use of an ion milling device, the Au layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, a Si solar cell having dots was completed (FIG. 7(f)).

For comparison, an Si solar cell that had dots but did not have an SiO₂ microscopic structures was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with an SiO₂ microscopic structures and dots had a preferred value of 11.2%. On the other hand, the photoelectric conversion efficiency of the Si solar cell that had dots but did not have an SiO₂ microscopic structures was 10.0%.

### Example 13

### Dots+SiN Structures

The same p-type Si substrate 12 as that of Example 1 was prepared. The surface of the p-type Si substrate 12 was doped with P by thermal diffusion, and a p-n⁺ junction was formed at 10²⁰ cm⁻³.

A solution formed by diluting an organic SOG composition (OCD-T7 5500-T (a trade name), manufactured by Tokyo Ohka Kogyo Co., Ltd.) with EL at 1:1 was spin-coated on the n⁺-type Si layer 11 at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG 500. The film thickness after the hardening was 50 nm.

A solution formed by dissolving 2 wt % of a polymer having a PMMA (Mw: 1500) mixed with a block polymer of a PS (Mw: 58000) and a PMMA (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds, to evaporate the solvent and achieve a film thickness of 80 nm.

The film was annealed for 4 hours at 210° C. in a nitrogen atmosphere, and a phase separation between the PS and the PMMA was performed to form a polystyrene dot pattern of approximately 70 nm in diameter (FIG. 5(a)).

After that, the film was etched by RIE for 15 seconds at an O₂ flow rate of 30 sccm, at a pressure of 13.3 Pa (100 mTorr), and with a power of 100 W. Through the RIE, the PMMA of the phase-separated PS-PMMA was selectively removed, to form a PS dot pattern (FIG. 5(b)).

With the PS dot pattern using as a mask, a SOG dot pattern was formed by RIE for 90 seconds at a CF₄ flow rate of 30 sccm, at a pressure of 1.33 Pa (10 mTorr), and with a power of 100 W (FIG. 5(c)).

With the SOG dot pattern using as a mask, Si was etched by RIE for 60 seconds at a Cl₂ flow rate of 15 sccm, at an Ar flow rate of 15 sccm, and with an RF power of 100 W. After the RIE using the chlorine gas, a pillar pattern that was 40 nm in size and was 50 nm in height was formed in the n⁺-type Si layer 11 (FIG. 5(d)).

A SiN film was then formed by ALD method on the n⁺-Si layer having the pillar pattern formed therein, and the Si pillar pattern was filled with SiN (FIG. 5(e)).

To remove the SiN portions formed on the filled n⁺-Si layer, the SiN was etched by RIE for 30 seconds at a CF₄ flow rate of 30 sccm, at a pressure of 1.33 Pa (10 mTorr), and with a power of 100 W, and the n⁺-Si layer was exposed. Through the above procedures, SiN microscopic structures were formed in the n⁺-Si layer (FIG. 5(f)).

A 100-nm thick Al layer 1 was formed on the bottom face of the substrate by a vapor deposition technique to form an electrode having an ohmic contact in the bottom face thereof. A 30-nm thick Ag layer 101 was then formed on the substrate surface by a vapor deposition technique (FIG. 6(a)).

A solution formed by diluting a resist (THMR IP3250, manufactured by Tokyo Ohka Kogyo Co., Ltd.) with ethyl lactate (EL) at 1:2 was spin-coated on the Ag layer 101 formed on the substrate surface at 3000 rpm for 30 seconds, and was then heated on a hot plate at 110° C. for 90 seconds to evaporate the solvent (FIG. 6(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 6(c)). After the imprint, the substrate was cooled to room temperature, and the quartz mold 310 was released (FIG. 6(d)). After the imprint, concave portions that were arranged in a dot pattern, were 60 nm in size, and were 70 nm in depth were formed in the resist 300.

The resist pattern 300 having the concave pattern was etched by RIE at a CF₄ flow rate of 30 sccm, at 10 mTorr, and with an RF power of 100 W. After the RIE using CF₄, bottom portions of the resist 300 were removed, and the Ag layer 101 was exposed (FIG. 7(e)).

With the use of an ion milling device, the Ag layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a Si solar cell having dots was completed (FIG. 7(f)).

For comparison, an Si solar cell that had dots but did not have an SiN microscopic structures was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the Si solar cell with an SiN microscopic structures and dots had a preferred value of 11.6%. On the other hand, the photoelectric conversion efficiency of the Si solar cell that had dots but did not have an SiN microscopic structures was 10.0%.

### Example 14

### Nano-Mesh+SiO₂ Thin Film

In the following example, the electrode 1 of Example 1 is formed as a substrate with an electrode in a solar cell. Polysilicon is used for the semiconductor layer. The layout of the components formed on and above the substrate with an electrode is the same as the layout shown in FIGS. 7(a) through 7(f), and therefore, this example is described with reference to FIGS. 7(a) through 7(f). The materials of the respective components are as follows.

A 5-μm thick p-type polysilicon layer 12 was formed by plasma CVD method using a mixed gas of SiH₄ and PH₃ on a glass substrate with an electrode 1.

A 0.3-μm thick n⁺-type polysilicon layer 11 was formed successively by CVD method. A 5-nm thick SiO₂ film 200 was then formed on the n⁺-type polysilicon layer 11 by CVD method.

A 30-nm thick Ag layer 101 was then formed on the surface of the SiO₂ film 200 by a vapor deposition technique (FIG. 7(a)).

A solution formed by diluting a resist 300 (THMR IP3250, manufactured by Tokyo Ohka Kogyo Co., Ltd.) with ethyl lactate (EL) at 1:2 was spin-coated on the Ag layer 101 at 2000 rpm for 30 seconds, and was then heated on a hot plate at 110° C. for 90 seconds to evaporate the solvent (FIG. 7(b)). The film thickness of the resist 300 was 150 nm. A quartz mold 310 (formed in an area of 9 cm²) having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist was being heated at 120° C. (FIG. 7(c)). After the imprint, the substrate 1 was cooled to room temperature, and the quartz mold 310 was released (FIG. 7(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist 300 were removed, and the Ag layer 101 was exposed (FIG. 7(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a polysilicon solar cell having a nano-mesh electrode was completed (FIG. 7(f)).

For comparison, a polysilicon solar cell that had a nano-mesh metal but did not have an SiO₂ film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the polysilicon solar cell with a 5-nm SiO₂ film and a nano-mesh metal had a preferred value of 8.5%. On the other hand, the photoelectric conversion efficiency of the polysilicon solar cell that had a nano-mesh metal but did not have an SiO₂ film was 7.5%.

As can be seen from the results, in the polysilicon solar cell, the photoelectric conversion efficiency became higher as the peak wavelength of electric field enhancement shifted toward the shorter-wavelength side by virtue of the insertion of an SiO₂ film.

### Example 15

### Nano-Mesh+SiN Thin Film

This example differs from Example 14 in that the SiO₂ film serving as the wavelength converting layer is replaced with a SiN film. The layout of the components formed on and above the electrode is the same as the layout shown in FIGS. 7(a) to 7(f), and therefore, this example is described with reference to FIGS. 7(a) to (f). A 5-μm thick p-type polysilicon layer 12 was formed by plasma CVD method using a mixed gas of SiH₄ and PH₃ on a glass substrate with an electrode 1.

A 0.3-μm thick n⁺-type polysilicon layer 11 was formed successively by CVD method. A 3-nm thick SiN film 200 was then formed on the n⁺-type polysilicon layer by CVD method.

A 30-nm thick Ag layer 101 was then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 2000 rpm for 30 seconds, and was then heated on a hot plate at 110° C. for 90 seconds to evaporate the solvent (FIG. 7(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist with a pressure of 10 MPa while the substrate with the resist was being heated at 120° C. (FIG. 7(c)). After the imprint, the substrate was cooled to room temperature, and the quartz mold was released (FIG. 7(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist 300 were removed, and the Ag layer 101 was exposed (FIG. 7(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a polysilicon solar cell having a nano-mesh electrode was completed (FIG. 7(f)).

For comparison, a polysilicon solar cell that had a nano-mesh metal but did not have an SiN film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the plysilicon solar cell with a 3-nm SiN film and a nano-mesh metal had a preferred value of 8.0%. On the other hand, the photoelectric conversion efficiency of the plysilicon solar cell that had a nano-mesh metal but did not have an SiN film was 7.5%.

As can be seen from the results, the photoelectric conversion efficiency became higher as the peak wavelength of electric field enhancement shifted toward the shorter-wavelength side by virtue of the insertion of an SiN film.

### Example 16

### Nano-Mesh+SiON Thin Film

This example differs from Example 14 in that the SiO₂ film serving as the wavelength converting layer is replaced with a SiON film. The components of this example are described with reference to FIGS. 7(a) through 7(f).

A 5-μm thick p-type polysilicon layer 12 was formed by plasma CVD method using a mixed gas of SiH₄ and PH₃ on a glass substrate with an electrode 1.

A 0.3-μm thick n⁺-type polysilicon layer 11 was formed successively by CVD method. A 3-nm thick SiON film 200 was then formed on the n⁺-type polysilicon layer 11 by CVD method.

A 30-nm thick Au layer 101 was then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Au layer 101 formed on the substrate surface at 2000 rpm for 30 seconds, and was then heated on a hot plate at 110° C. for 90 seconds to evaporate the solvent (FIG. 7(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist 300 was being heated at 120° C. (FIG. 7(c)). After the imprint, the substrate was cooled to room temperature, and the quartz mold 310 was released (FIG. 7(d)). After the imprint, concave portions that were arranged at a pitch of 200 nm, were 100 nm in size, and were 100 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist 300 were removed, and the Au layer 101 was exposed (FIG. 7(e)).

With the use of an ion milling device, the Au layer 101 was etched by the ion milling for 90 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, a polysilicon solar cell having a nano-mesh electrode was completed (FIG. 7(f)).

For comparison, a polysilicon solar cell that had a nano-mesh metal but did not have an SiON film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the polysilicon solar cell with a 3-nm SiON film and a nano-mesh metal had a preferred value of 8.2%. On the other hand, the photoelectric conversion efficiency of the polysilicon solar cell that had a nano-mesh metal but did not have an SiON film was 7.5%.

As can be seen from the results, the photoelectric conversion efficiency became higher as the peak wavelength of electric field enhancement shifted toward the shorter-wavelength side by virtue of the insertion of an SiON film.

### Example 17

### Dots+SiO₂ Thin Film

In this example, the wavelength converting layer is formed with a SiO₂ film. This example differs from Example 14 in that the microscopic structures are miniature structures arranged in a dot pattern spreading in a plane perpendicular to the stacking direction. The components of this example are described with reference to FIGS. 7(a) through 7(f).

A 5-μm thick p-type polysilicon layer 12 was formed by plasma CVD method using a mixed gas of SiH₄ and PH₃ on a glass substrate with an electrode 1. The layout of the components formed on and above the electrode 1 is the same as the layout shown in FIGS. 7(a) through 7(f), and therefore, this example is described with reference to FIGS. 7(a) through 7(f). The materials of the respective components are as follows.

A 0.3-μm thick n⁺-type polysilicon layer 11 was formed successively by CVD method. A 3-nm thick SiO₂ film 200 was then formed on the n⁺-type polysilicon layer 11 by CVD method.

A 30-nm thick Au layer 101 was then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Au layer 101 formed on the substrate surface at 3000 rpm for 30 seconds, and was then heated on a hot plate at 110° C. for 90 seconds to evaporate the solvent (FIG. 7(b)). The film thickness of the resist was 120 nm. A quartz mold (formed in an area of 9 cm²) having concave portions that were 60 nm in size and were 100 nm in height was prepared. Imprint was then performed by pushing the convex portions of the quartz mold against the resist with a pressure of 10 MPa while the substrate with the resist was being heated at 120° C. (FIG. 7(c)). After the imprint, the substrate was cooled to room temperature, and the quartz mold was released (FIG. 7(d)). After the imprint, concave portions that were arranged in a dot pattern, were 60 nm in size, and were 70 nm in depth were formed in the resist.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist 300 were removed, and the Au layer 101 was exposed (FIG. 7(e)).

With the use of an ion milling device, the Au layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, a polysilicon solar cell having dots was completed (FIG. 7(f)).

For comparison, a polysilicon solar cell that had dots but did not have an SiO₂ film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the polysilicon solar cell with a 3-nm SiO₂ film and dots had a preferred value of 8.5%. On the other hand, the photoelectric conversion efficiency of the polysilicon solar cell that had dots but did not have an SiO₂ film was 7.5%.

### Example 18

### Dots+SiON Thin Film

This example differs from Example 14 in that the SiO₂ film serving as the wavelength converting layer is replaced with a SiON film, and the microscopic structures are miniature structures arranged in a dot pattern spreading in a plane perpendicular to the stacking direction. The components of this example are described with reference to FIGS. 7(a) through 7(f).

A 5-μm thick p-type polysilicon layer was formed by plasma CVD method using a mixed gas of SiH₄ and PH₃, on a glass substrate with an electrode. The layout of the components formed on and above the electrode is the same as the layout shown in FIGS. 7(a) through 7(f), and therefore, this example is described with reference to FIGS. 7(a) through 7(f). The materials of the respective components are as follows.

A 0.3-μm thick n⁺-type polysilicon layer was formed successively by CVD method. A 4-nm thick SiON film was then formed on the n⁺-type polysilicon layer by CVD method.

A 30-nm thick Ag layer was then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 3000 rpm for 30 seconds, and was then heated on a hot plate at 110° C. for 90 seconds to evaporate the solvent (FIG. 7(b)). The film thickness of the resist was 120 nm. A quartz mold (formed in an area of 9 cm²) having concave portions that were 60 nm in size and were 100 nm in height was prepared. Imprint was then performed by pushing the convex portions of the quartz mold against the resist with a pressure of 10 MPa while the substrate with the resist was being heated at 120° C. (FIG. 7(c)). After the imprint, the substrate was cooled to room temperature, and the quartz mold was released (FIG. 7(d)). After the imprint, concave portions that were arranged in a dot pattern, were 60 nm in size, and were 70 nm in depth were formed in the resist.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist 300 were removed, and the Ag layer 101 was exposed (FIG. 7(e)).

With the use of an ion milling device, the Ag layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, a polysilicon solar cell having dots was completed (FIG. 7(f)).

For comparison, a polysilicon solar cell that had dots but did not have an SiON film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the polysilicon solar cell with a 4-nm SiON film and dots had a preferred value of 8.3%. On the other hand, the photoelectric conversion efficiency of the polysilicon solar cell that had dots but did not have an SiO₂ film was 7.5%.

### Example 19

### Nano-Mesh+SiN Structures

This example differs from Example 14 in that the SiO₂ film serving as the wavelength converting layer is replaced with pillar-like SiN structures. The components of this example are described with reference to FIGS. 5(a) through 6(f).

A 5-μm thick p-type polysilicon layer 12 was formed by plasma CVD method using a mixed gas of SiH₄ and PH₃ on a glass substrate 1 with an electrode.

A 0.3-μm thick n⁺-type polysilicon layer 11 was formed successively by CVD method.

A solution formed by diluting an organic SOG composition 500 (OCD-T7 5500-T (a trade name), manufactured by Tokyo Ohka Kogyo Co., Ltd.) with EL at 1:1 was spin-coated on the n⁺-type polysilicon layer 11 at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG. The film thickness after the hardening was 50 nm.

A solution formed by dissolving 2 wt % of a polymer having a PMMA 402 (Mw: 1500) mixed with a block polymer of a PS 401 (Mw: 58000) and a PMMA 402 (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 80 nm.

The film was annealed for 4 hours at 210° C. in a nitrogen atmosphere, and a phase separation between the PS 401 and the PMMA 402 was performed to form a polystyrene dot pattern of approximately 70 nm in diameter (FIG. 5(a)).

After that, the film was etched by RIE for 15 seconds at an O₂ flow rate of 30 sccm, at a pressure of 13.3 Pa (100 mTorr), and with a power of 100 W. Through the RIE, the PMMA of the phase-separated PS-PMMA was selectively removed to form a PS dot pattern 403 (FIG. 5(b)).

With the PS dot pattern 403 using as a mask, a SOG dot pattern 501 was formed by RIE for 90 seconds at a CF₄ flow rate of 30 sccm, at a pressure of 1.33 Pa (10 mTorr), and with a power of 100 W (FIG. 5(c)).

With the SOG dot pattern 501 using as a mask, Si was etched by RIE for 60 seconds at a Cl₂ flow rate of 15 sccm, at an Ar flow rate of 15 sccm, and with an RF power of 100 W. After the RIE using the chlorine gas, a pillar pattern 121 that was 40 nm in size and was 50 nm in height was formed in the n⁺-type polysilicon layer (FIG. 5(d)).

A SiN film 203 was then formed by ALD method on the n⁺-layer having the pillar pattern formed therein, and the Si pillar pattern 121 was filled with SiN (FIG. 5(e)).

To remove the SiN portions formed on the filled n⁺-type polysilicon layer 11, the SiN was etched by RIE for 30 seconds at a CF₄ flow rate of 30 sccm, at a pressure of 1.33 Pa (10 mTorr), and with a power of 100 W, and the n⁺-type polysilicon layer was exposed. Through the above procedures, SiN microscopic structures were formed in the n⁺-type polysilicon layer (FIG. 5(f)).

A 30-nm thick Au layer 101 was then formed on the substrate surface by a vapor deposition technique (FIG. 6(a)).

A solution formed by diluting a resist 300 (THMR IP3250, manufactured by Tokyo Ohka Kogyo Co., Ltd.) with ethyl lactate (EL) at 1:2 was spin-coated on the Au layer 101 formed on the substrate surface at 2000 rpm for 30 seconds, and was then heated on a hot plate at 110° C. for 90 seconds to evaporate the solvent (FIG. 6(b)). The film thickness of the resist 300 was 150 nm. A quartz mold 310 (formed in an area of 9 cm²) having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist 300 was being heated at 120° C. (FIG. 6(c)). After the imprint, the substrate was cooled to room temperature, and the quartz mold was released (FIG. 6(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W. After the RIE using CF₄, bottom portions of the resist 300 were removed, and the Au layer 101 was exposed (FIG. 6(e)).

With the use of an ion milling device, the Au layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, a polysilicon solar cell having a nano-mesh electrode was completed (FIG. 6(f)).

For comparison, a polysilicon solar cell that had a nano-mesh metal but did not have SiN microscopic structures was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the polysilicon solar cell with SiN microscopic structures and a nano-mesh metal 101 had a preferred value of 8.2%. On the other hand, the photoelectric conversion efficiency of the polysilicon solar cell that had a nano-mesh metal but did not have SiN microscopic structures was 7.5%.

### Example 20

### Dots+SiO₂ Structures

This example differs from Example 14 in that the SiO₂ film serving as the wavelength converting layer is replaced with pillar-like SiO₂ structures, and the microscopic structures are arranged in a dot pattern. The components of this example are described with reference to FIGS. 5(a) through 6(f).

A 5-μm thick p-type polysilicon layer was formed by plasma CVD method using a mixed gas of SiH₄ and PH₃ on a glass substrate with an electrode.

A 0.3-μm thick n⁺-type polysilicon layer was formed successively by CVD method. A solution formed by diluting an organic SOG composition (OCD-T7 5500-T (a trade name), manufactured by Tokyo Ohka Kogyo Co., Ltd.) with EL at 1:1 was spin-coated on the n⁺-layer at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG. The film thickness after the hardening was 50 nm.

A solution formed by dissolving 2 wt % of a polymer having a PMMA (Mw: 1500) mixed with a block polymer of a PS (Mw: 58000) and a PMMA (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 80 nm.

The film was annealed for 4 hours at 210° C. in a nitrogen atmosphere, and a phase separation between the PS and the PMMA was performed to form a polystyrene dot pattern of approximately 70 nm in diameter (FIG. 5(a)).

After that, the film was etched by RIE for 15 seconds at an O₂ flow rate of 30 sccm, at a pressure of 13.3 Pa (100 mTorr), and with a power of 100 W. Through the RIE, the PMMA of the phase-separated PS-PMMA was selectively removed to form a PS dot pattern (FIG. 5(b)).

With the PS dot pattern using as a mask, a SOG dot pattern was formed by RIE for 90 seconds at a CF₄ flow rate of 30 sccm, at a pressure of 1.33 Pa (10 mTorr), and with a power of 100 W (FIG. 5(c)).

With the SOG dot pattern using as a mask, Si was etched by RIE for 60 seconds at a Cl₂ flow rate of 15 sccm, at an Ar flow rate of 15 sccm, and with an RF power of 100 W. After the RIE using the chlorine gas, a pillar pattern that was 40 nm in size and was 50 nm in height was formed in the n⁺-layer (FIG. 5(d)).

A SiO₂ film was then formed by ALD method on the n⁺-layer having the pillar pattern formed therein, and the Si pillar pattern was filled with SiO₂ (FIG. 5(e)).

To remove the SiO₂ portions formed on the filled n⁺-layer, the SiO₂ was etched by RIE for 30 seconds at a CF₄ flow rate of 30 sccm, at a pressure of 1.33 Pa (10 mTorr), and with a power of 100 W, and the n⁺-layer was exposed. Through the above procedures, SiO₂ microscopic structures were formed in the n⁺-layer (FIG. 5(f)).

A 30-nm thick Ag layer was then formed on the substrate surface by a vapor deposition technique (FIG. 6(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 3000 rpm for 30 seconds, and was then heated on a hot plate at 110° C. for 90 seconds to evaporate the solvent (FIG. 6(b)). The film thickness of the resist was 120 nm. A quartz mold (formed in an area of 9 cm²) having convex portions that were 60 nm in size and were 100 nm in height was prepared. Imprint was then performed by pushing the convex portions of the quartz mold against the resist with a pressure of 10 MPa while the substrate with the resist was being heated at 120° C. (FIG. 6(c)). After the imprint, the substrate was cooled to room temperature, and the quartz mold was released (FIG. 6(d)). After the imprint, concave portions that were arranged in a dot pattern, were 60 nm in size, and were 70 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist 300 were removed, and the Ag layer 101 was exposed (FIG. 6(e)).

With the use of an ion milling device, the Ag layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a polysilicon solar cell having dots was completed (FIG. 6(f)).

For comparison, a polysilicon solar cell that had dots but did not have SiO₂ microscopic structures was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the polysilicon solar cell with an SiO₂ microscopic structures and dots had a preferred value of 8.0%. On the other hand, the photoelectric conversion efficiency of the polysilicon solar cell that had dots but did not have an SiO₂ microscopic structures was 7.5%.

### Example 21

### Nano-Mesh+SiO₂ Thin Film

In the following example, amorphous silicon is used for the semiconductor layer. A mesh-like microscopic structure is used, and a SiO₂ thin film is used as the wavelength converting layer. The components of this example are described with reference to FIGS. 7(a) through 7(f).

A 5-μm thick p-type amorphous silicon layer was formed by plasma CVD method using a mixed gas of SiH₄ and PH₃ on a glass substrate with an electrode.

A 0.3-μm thick n⁺-type amorphous silicon layer was formed successively by CVD method. A 5-nm thick SiO₂ film was then formed on the n⁺-type amorphous silicon layer by CVD method.

A 30-nm thick Ag layer was then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 2000 rpm for 30 seconds, and was then heated on a hot plate at 110° C. for 90 seconds to evaporate the solvent (FIG. 7(b)). The film thickness of the resist was 150 nm. A quartz mold (formed in an area of 9 cm²) having convex portions that were arranged at a pitch of 200 nm, were 100 nm in size, and were 150 nm in height was prepared. Imprint was then performed by pushing the convex portions of the quartz mold against the resist with a pressure of 10 MPa while the substrate with the resist was being heated at 120° C. (FIG. 7(c)). After the imprint, the substrate was cooled to room temperature, and the quartz mold was released (FIG. 7(d)). After the imprint, concave portions that were arranged at a pitch of 200 nm, were 100 nm in size, and were 100 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer was exposed (FIG. 7(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, an amorphous Si solar cell having a nano-mesh electrode was completed (FIG. 7(f)).

For comparison, an amorphous Si solar cell that had a nano-mesh metal but did not have an SiO₂ film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the amorphous Si solar cell with a 5-nm SiO₂ film and a nano-mesh metal had a preferred value of 6.5%. On the other hand, the photoelectric conversion efficiency of the amorphous Si solar cell that had a nano-mesh metal but did not have an SiO₂ film was 5.0%.

As can be seen from the results, in the amorphous Si solar cell, the photoelectric conversion efficiency became higher as the peak wavelength of electric field enhancement shifted toward the shorter-wavelength side by virtue of the insertion of an SiO₂ film.

### Example 22

### Nano-Mesh+SiN Thin Film

This example differs from Example 21 in that the SiO₂ thin film serving as the wavelength converting layer is replaced with a SiN thin film. The components of this example are described with reference to FIGS. 7(a) through 7(f).

A 5-μm thick p-type amorphous silicon layer 12 was formed by plasma CVD method using a mixed gas of SiH₄ and PH₃ on a glass substrate with an electrode.

A 0.3-μm thick n⁺-type amorphous silicon layer 11 was formed successively by CVD method. A 3-nm thick SiN film 200 was then formed on the n⁺-type amorphous silicon layer 11 by CVD method.

A 30-nm thick Ag layer 101 as then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 2000 rpm for 30 seconds, and was then heated on a hot plate at 110° C. for 90 seconds to evaporate the solvent (FIG. 7(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist was being heated at 120° C. (FIG. 7(c)). After the imprint, the substrate was cooled to room temperature, and the quartz mold 310 was released (FIG. 7(d)). After the imprint, concave portions that were arranged at a pitch of 200 nm, were 100 nm in size, and were 100 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer was exposed (FIG. 7(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, an amorphous Si solar cell having a nano-mesh electrode was completed (FIG. 7(f)).

For comparison, an amorphous Si solar cell that had a nano-mesh metal but did not have an SiN film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the amorphous Si solar cell with a 3-nm SiN film and a nano-mesh metal 101 had a preferred value of 6.3%. On the other hand, the photoelectric conversion efficiency of the amorphous Si solar cell that had a nano-mesh metal but did not have an SiN film was 5.0%.

As can be seen from the results, in the amorphous Si solar cell, the photoelectric conversion efficiency became higher as the peak wavelength of electric field enhancement shifted toward the shorter-wavelength side by virtue of the insertion of an SiN film.

### Example 23

### Nano-Mesh+SiON Thin Film

This example differs from Example 21 in that the SiO₂ thin film serving as the wavelength converting layer is replaced with a SiON thin film. The components of this example are described with reference to FIGS. 7(a) through 7(f).

A 5-μm thick p-type amorphous silicon layer was formed by plasma CVD method using a mixed gas of SiH₄ and PH₃, on a glass substrate with an electrode.

A 0.3-μm thick n⁺-type amorphous silicon layer was formed successively by CVD method. A 3-nm thick SiON film was then formed on the n⁺-type amorphous silicon layer by CVD method.

A 30-nm thick Au layer was then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Au layer formed on the substrate surface at 2000 rpm for 30 seconds, and was then heated on a hot plate at 110° C. for 90 seconds to evaporate the solvent (FIG. 7(b)). The film thickness of the resist was 150 nm. A quartz mold (formed in an area of 9 cm²) having convex portions that were arranged at a pitch of 200 nm, were 100 nm in size, and were 150 nm in height was prepared. Imprint was then performed by pushing the convex portions of the quartz mold against the resist with a pressure of 10 MPa while the substrate with the resist was being heated at 120° C. (FIG. 7(c)). After the imprint, the substrate was cooled to room temperature, and the quartz mold was released (FIG. 7(d)). After the imprint, concave portions that were arranged at a pitch of 200 nm, were 100 nm in size, and were 100 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer was exposed (FIG. 7(e)).

With the use of an ion milling device, the Ag layer 101 was etched by the ion milling for 90 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, an amorphous Si solar cell having a nano-mesh electrode was completed (FIG. 7(f)).

For comparison, an amorphous Si solar cell that had a nano-mesh metal but did not have an SiON film was also manufactured in the same manner as above. PS (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the amorphous Si solar cell with a 3-nm SiON film and a nano-mesh metal had a preferred value of 6.4%. On the other hand, the photoelectric conversion efficiency of the amorphous Si solar cell that had a nano-mesh metal but did not have an SiON film was 5.0%.

As can be seen from the results, in the amorphous Si solar cell, the photoelectric conversion efficiency became higher as the peak wavelength of electric field enhancement shifted toward the shorter-wavelength side by virtue of the insertion of an SiON film.

### Example 24

### Dots+SiO₂ Thin Film

This example differs from Example 21 in that the microscopic structures are miniature structures arranged in a dot pattern spreading in a plane perpendicular to the stacking direction. The components of this example are described with reference to FIGS. 7(a) through 7(f).

A 5-μm thick p-type amorphous silicon layer 12 was formed by plasma CVD method using a mixed gas of SiH₄ and PH₃ on a glass substrate with an electrode.

A 0.3-μm thick n⁺-type amorphous silicon layer 11 was formed successively by CVD method. A 3-nm thick SiO₂ film 200 was then formed on the n⁺-type amorphous silicon layer 11 by CVD method.

A 30-nm thick Au layer 101 was then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Au layer formed on the substrate surface at 3000 rpm for 30 seconds, and was then heated on a hot plate at 110° C. for 90 seconds to evaporate the solvent (FIG. 7(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 7(c)). After the imprint, the substrate was cooled to room temperature, and the quartz mold 310 was released (FIG. 7(d)). After the imprint, concave portions that were arranged in a dot pattern, were 60 nm in size, and were 70 nm in depth were formed in the resist.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist 300 were removed, and the Au layer 101 was exposed (FIG. 7(e)).

With the use of an ion milling device, the Au layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, an amorphous silicon solar cell having dots was completed (FIG. 7(f)).

For comparison, an amorphous silicon solar cell that had dots but did not have an SiO₂ film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the amorphous silicon solar cell with a 3-nm SiO₂ film and dots had a preferred value of 6.3%. On the other hand, the photoelectric conversion efficiency of the amorphous silicon solar cell that had dots but did not have an SiO₂ film was 5.0%.

### Example 25

### Dots+SiON Thin Film

This example differs from Example 21 in that the metal electrode has a dot pattern spreading in a plane perpendicular to the stacking direction, and, instead of the SiO₂ thin film, a SiON thin film is used as the wavelength converting layer. The components of this example are described with reference to FIGS. 7(a) through 7(f).

A 5-μm thick p-type amorphous silicon layer 12 was formed by plasma CVD method using a mixed gas of SiH₄ and PH₃ on a glass substrate with an electrode.

A 0.3-μm thick n⁺-type amorphous silicon layer 11 was formed successively by CVD method. A 4-nm thick SiON film 200 was then formed on the n⁺-type amorphous silicon layer 11 by CVD method.

A 30-nm thick Ag layer 101 was then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 3000 rpm for 30 seconds, and was then heated on a hot plate at 110° C. for 90 seconds to evaporate the solvent (FIG. 7(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist was being heated at 120° C. (FIG. 7(c)). After the imprint, the substrate was cooled to room temperature, and the quartz mold 310 was released (FIG. 7(d)). After the imprint, concave portions that were arranged in a dot pattern, were 60 nm in size, and were 70 nm in depth were formed in the resist.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist 300 were removed, and the Ag layer 101 was exposed (FIG. 7(e)).

With the use of an ion milling device, the Ag layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, an amorphous silicon solar cell having dots was completed (FIG. 7(f)).

For comparison, an amorphous silicon solar cell that had dots but did not have an SiON film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the amorphous silicon solar cell with a 4-nm SiON film and dots had a preferred value of 6.2%. On the other hand, the photoelectric conversion efficiency of the amorphous silicon solar cell that had dots but did not have an SiON film was 5.0%.

### Example 26

### Nano-Mesh+SiN Structures

This example differs from Example 21 in that, instead of the SiO₂ thin film, pillar-like SiN structures are used as the wavelength converting layer. The components of this example are described with reference to FIGS. 5(a) through 6(f).

A 5-μm thick p-type amorphous silicon layer 12 was formed by plasma CVD method using a mixed gas of SiH₄ and PH₃ on a glass substrate with an electrode 1.

A 0.3-μm thick n⁺-type amorphous silicon layer 11 was formed successively by CVD method. A solution formed by diluting an organic SOG composition (OCD-T7 5500-T (a trade name), manufactured by Tokyo Ohka Kogyo Co., Ltd.) with EL at 1:1 was spin-coated on the n⁺-type amorphous silicon layer 11 at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG. The film thickness after the hardening was 50 nm.

A solution formed by dissolving 2 wt % of a polymer having a PMMA (Mw: 1500) mixed with a block polymer of a PS (Mw: 58000) and a PMMA (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 80 nm.

The film was annealed for 4 hours at 210° C. in a nitrogen atmosphere, and a phase separation between the PS and the PMMA was performed to form a polystyrene dot pattern of approximately 70 nm in diameter (FIG. 5(a)).

After that, the film was etched by RIE for 15 seconds at an O₂ flow rate of 30 sccm, at a pressure of 13.3 Pa (100 mTorr), and with a power of 100 W. Through the RIE, the PMMA of the phase-separated PS-PMMA was selectively removed to form a PS dot pattern (FIG. 5(b)).

With the PS dot pattern using as a mask, a SOG dot pattern was formed by RIE for 90 seconds at a CF₄ flow rate of 30 sccm, at a pressure of 1.33 Pa (10 mTorr), and with a power of 100 W (FIG. 5(c)).

With the SOG dot pattern using as a mask, Si was etched by

RIE for 60 seconds at a Cl₂ flow rate of 15 sccm, at an Ar flow rate of 15 sccm, and with an RF power of 100 W. After the RIE using the chlorine gas, a pillar pattern that was 40 nm in size and was 50 nm in height was formed in the n⁺-type amorphous silicon layer (FIG. 5(d)).

A SiN film was then formed by ALD method on the n⁺-type amorphous silicon layer having the pillar pattern formed therein, and the Si pillar pattern was filled with SiN (FIG. 5(e)).

To remove the SiN portions formed on the filled n⁺-type amorphous silicon layer, the SiN was etched by RIE at a CF₄ flow rate of 30 sccm, at a pressure of 1.33 Pa (10 mTorr), and with a power of 100 W, and the n⁺-layer was exposed. Through the above procedures, SiN microscopic structures were formed in the n⁺-type amorphous silicon layer (FIG. 5(f)).

A 30-nm thick Au layer 101 was then formed on the substrate surface by a vapor deposition technique (FIG. 6(a)).

A solution formed by diluting a resist (THMR IP3250, manufactured by Tokyo Ohka Kogyo Co., Ltd.) with ethyl lactate (EL) at 1:2 was spin-coated on the Au layer formed on the substrate surface at 2000 rpm for 30 seconds, and was then heated on a hot plate at 110° C. for 90 seconds to evaporate the solvent (FIG. 6(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist was being heated at 120° C. (FIG. 6(c)). After the imprint, the substrate was cooled to room temperature, and the quartz mold 310 was released (FIG. 6(d)). After the imprint, concave portions that were arranged at a pitch of 200 nm, were 100 nm in size, and were 100 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Au layer was exposed (FIG. 6(e)).

With the use of an ion milling device, the Au layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, an amorphous Si solar cell having a nano-mesh electrode was completed (FIG. 6(f)).

For comparison, an amorphous Si solar cell that had a nano-mesh metal but did not have an SiN microscopic structures was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the amorphous Si solar cell with an SiN microscopic structures and a nano-mesh metal had a preferred value of 5.9%. On the other hand, the photoelectric conversion efficiency of the amorphous Si solar cell that had a nano-mesh metal but did not have an SiN microscopic structures was 5.0%.

### Example 27

### Dots+SiO₂ Structures

This example differs from Example 21 in that, instead of the SiO₂ thin film, pillar-like SiO₂ structures are used as the wavelength converting layer, and the microscopic structures are miniature structures arranged in a dot pattern spreading in a plane perpendicular to the stacking direction. The components of this example are described with reference to FIGS. 7(a) through 7(f).

A 5-μm thick p-type amorphous silicon layer 12 was formed by plasma CVD method using a mixed gas of SiH₄ and PH₃ on a glass substrate with an electrode 1. The layout of the components formed on and above the electrode is the same as the layout shown in FIGS. 5(a) through 6(f), and therefore, this example is described with reference to FIGS. 5(a) through 6(f). The materials of the respective components are described as follows.

A 0.3-μm thick n⁺-type amorphous silicon layer 11 was formed successively by CVD method. A solution formed by diluting an organic SOG composition (OCD-T7 5500-T (a trade name), manufactured by Tokyo Ohka Kogyo Co., Ltd.) with EL at 1:1 was spin-coated on the n⁺-type amorphous silicon layer at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG 500. The film thickness after the hardening was 50 nm.

A solution formed by dissolving 2 wt % of a polymer having a PMMA (Mw: 1500) mixed with a block polymer of a PS (Mw: 58000) and a PMMA (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 80 nm.

The film was annealed for 4 hours at 210° C. in a nitrogen atmosphere, and a phase separation between the PS and the PMMA was performed to form a polystyrene dot pattern of approximately 70 nm in diameter (FIG. 5(a)).

After that, the film was etched by RIE for 15 seconds at an O₂ flow rate of 30 sccm, at a pressure of 13.3 Pa (100 mTorr), and with a power of 100 W. Through the RIE, the PMMA of the phase-separated PS-PMMA was selectively removed to form a PS dot pattern (FIG. 5(b)).

With the PS dot pattern using as a mask, a SOG dot pattern was formed by RIE for 90 seconds at a CF₄ flow rate of 30 sccm, at a pressure of 1.33 Pa (10 mTorr), and with a power of 100 W (FIG. 5(c)).

With the SOG dot pattern using as a mask, Si was etched by RIE for 60 seconds at a Cl₂ flow rate of 15 sccm, at an Ar flow rate of 15 sccm, and with an RF power of 100 W. After the RIE using the chlorine gas, a pillar pattern that was 40 nm in size and was 50 nm in height was formed in the n⁺-type amorphous silicon layer (FIG. 5(d)).

A SiO₂ film was then formed by ALD method on the n⁺-type amorphous silicon layer having the pillar pattern formed therein, and the Si pillar pattern was filled with SiO₂ (FIG. 5(e)).

To remove the SiO₂ portions formed on the filled n⁺-type amorphous silicon layer, the SiO₂ was etched by RIE for 30 seconds at a CF₄ flow rate of 30 sccm, at a pressure of 1.33 Pa (10 mTorr), and with a power of 100 W, and the n⁺-type amorphous silicon layer was exposed. Through the above procedures, SiO₂ microscopic structures were formed in the n⁺-type amorphous silicon layer (FIG. 5(f)).

A 30-nm thick Ag layer 101 was then formed on the substrate surface by a vapor deposition technique (FIG. 6(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 3000 rpm for 30 seconds, and was then heated on a hot plate at 110° C. for 90 seconds to evaporate the solvent (FIG. 6(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 6(c)). After the imprint, the substrate was cooled to room temperature, and the quartz mold 310 was released (FIG. 6(d)). After the imprint, concave portions that were arranged in a dot pattern, were 60 nm in size, and were 70 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer was exposed (FIG. 6(e)).

With the use of an ion milling device, the Ag layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, an amorphous Si solar cell having dots was completed (FIG. 6(f)).

For comparison, an amorphous Si solar cell that had dots but did not have an SiO₂ microscopic structures was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the amorphous Si solar cell with an SiO₂ microscopic structures and dots had a preferred value of 6.0%. On the other hand, the photoelectric conversion efficiency of the amorphous Si solar cell that had dots but did not have an SiO₂ microscopic structures was 5.0%.

### Example 28

### Nano-Mesh+SiO₂ Thin Film

An example case where GaAs is used for the semiconductor layer is described below. In this example, a mesh-like electrode is used as the microscopic structures, and a SiO₂ thin film is used as the wavelength converting layer. The layout of the components is the same as that shown in FIGS. 7(a) through 7(f), and therefore, this example is described with reference to FIGS. 7(a) through 7(f).

A p-type GaAs substrate 12 having a doping concentration of 10¹⁶ cm⁻³ was prepared. A 0.2-μm thick n⁺-type GaAs layer 11 was formed on the p-type GaAs substrate 12 by MOCVD (Metal Organic Chemical Vapor Deposition).

A 100-nm thick Au—Ge (1%) layer 1 was then formed on the bottom face of the p-type GaAs substrate 12 by a vapor deposition technique. After the formation, the GaAs substrate was annealed for 30 minutes at 450° C. in a nitrogen atmosphere. After the annealing, an electrode 1 having an ohmic contact in the bottom face thereof was formed.

A 5-nm thick SiO₂ film 200 was then formed on the n⁺-type GaAs layer by CVD method.

A 30-nm thick Ag layer 101 was then formed on the substrate surface by a vapor deposition technique (FIG. 7(a)).

A solution formed by diluting a resist 300 (THMR IP3250, manufactured by Tokyo Ohka Kogyo Co., Ltd.) with ethyl lactate (EL) at 1:2 was spin-coated on the Ag layer 101 formed on the substrate surface at 2000 rpm for 30 seconds, and was then heated on a hot plate at 110° C. for 90 seconds to evaporate the solvent (FIG. 7(b)). The film thickness of the resist 300 was 150 nm. A quartz mold 310 (formed in an area of 9 cm²) having convex portions that were arranged at a pitch of 150 nm, were 100 nm in size, and were 150 nm in height was prepared. Imprint was then performed by pushing the convex portions of the quartz mold 310 against the resist 300 with a pressure of 10 MPa while the substrate with the resist was being heated at 120° C. (FIG. 7(c)). After the imprint, the substrate was cooled to room temperature, and the quartz mold 310 was released (FIG. 7(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer was exposed (FIG. 7(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a GaAs solar cell having a nano-mesh metal was completed (FIG. 7(f)).

For comparison, a GaAs solar cell that had a nano-mesh metal but did not have an SiO₂ film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the GaAs solar cell with an SiO₂ film and a nano-mesh metal had a preferred value of 10.0%. On the other hand, the photoelectric conversion efficiency of the GaAs solar cell that had nano-mesh metal but did not have an SiO₂ film was 8.5%.

As can be seen from the results, in the GaAs solar cell, the photoelectric conversion efficiency became higher as the peak wavelength of electric field enhancement shifted toward the shorter-wavelength side by virtue of the insertion of an SiO₂ film.

### Example 29

### Nano-Mesh+SiN Thin Film

This example differs from Example 28 in that a SiN thin film is used as the wavelength converting layer. The layout of the components is the same as that shown in FIGS. 7(a) through 7(f), and therefore, this example is described with reference to FIGS. 7(a) through 7(f).

A p-type GaAs substrate 11 having a doping concentration of 10¹⁶ cm⁻³ was prepared. A 0.2 μm thick n⁺-type GaAs layer 12 was formed on the p-type GaAs substrate by MOCVD method.

A 100-nm thick Au—Ge (1%) layer was then formed on the bottom face of the p-type GaAs substrate by a vapor deposition technique. After the formation, the GaAs substrate was annealed for 30 minutes at 450° C. in a nitrogen atmosphere. After the annealing, an electrode 1 having an ohmic contact in the bottom face thereof was formed.

A 3-nm thick SiN film 200 was then formed on the n⁺-type GaAs layer by CVD method.

A 30-nm thick Ag layer 101 was then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 2000 rpm for 30 seconds, and was then heated on a hot plate at 110° C. for 90 seconds to evaporate the solvent (FIG. 7(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist was being heated at 120° C. (FIG. 7(c)). After the imprint, the substrate was cooled to room temperature, and the quartz mold 310 was released (FIG. 7(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer 101 was exposed (FIG. 7(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a GaAs solar cell having a nano-mesh metal was completed (FIG. 7(f)).

For comparison, a GaAs solar cell that had a nano-mesh metal but did not have an SiN film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the GaAs solar cell with an SiN film and a nano-mesh metal had a preferred value of 9.9%. On the other hand, the photoelectric conversion efficiency of the GaAs solar cell that had nano-mesh metal but did not have an SiN film was 8.5%.

As can be seen from the results, in the GaAs solar cell, the photoelectric conversion efficiency became higher as the peak wavelength of electric field enhancement shifted toward the shorter-wavelength side by virtue of the insertion of an SiN film.

### Example 30

### Nano-Mesh+SiON Thin Film

This example differs from Example 28 in that a SiON thin film is used as the wavelength converting layer. The layout of the components is the same as that shown in FIGS. 7(a) through 7(f), and therefore, this example is described with reference to FIGS. 7(a) through 7(f).

A p-type GaAs substrate 12 having a doping concentration of 10¹⁶ cm⁻³ was prepared. A 0.2-μm thick n⁺-type GaAs layer 11 was formed on the p-type GaAs substrate 12 by MOCVD method.

A 100-nm thick Au—Ge (1%) layer was then formed on the bottom face of the p-type GaAs substrate by a vapor deposition technique. After the formation, the GaAs substrate was annealed for 30 minutes at 450° C. in a nitrogen atmosphere. After the annealing, an electrode 1 having an ohmic contact in the bottom face thereof was formed.

A 3-nm thick SiON film 200 was then formed on the n⁺-type GaAs layer by CVD method.

A 30-nm thick Au layer 101 was then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Au layer formed on the substrate surface at 2000 rpm for 30 seconds, and was then heated on a hot plate at 110° C. for 90 seconds to evaporate the solvent (FIG. 7(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist 300 was being heated at 120° C. (FIG. 7(c)). After the imprint, the substrate was cooled to room temperature, and the quartz mold 310 was released (FIG. 7(d)). After the imprint, concave portions that were arranged at a pitch of 200 nm, were 100 nm in size, and were 100 nm in depth were formed in the resist.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Au layer 101 was exposed (FIG. 7(e)).

With the use of an ion milling device, the Au layer 101 was etched by the ion milling for 90 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, a GaAs solar cell having a nano-mesh metal was completed (FIG. 7(f)).

For comparison, a GaAs solar cell that had a nano-mesh metal but did not have an SiON film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the GaAs solar cell with an SiON film and a nano-mesh metal had a preferred value of 10.0%. On the other hand, the photoelectric conversion efficiency of the GaAs solar cell that had nano-mesh metal but did not have an SiON film was 8.5%.

As can be seen from the results, in the GaAs solar cell, the photoelectric conversion efficiency became higher as the peak wavelength of electric field enhancement shifted toward the shorter-wavelength side by virtue of the insertion of an SiON film.

### Example 31

### Dots+SiO₂ Thin Film

This example differs from Example 28 in that the microscopic structures are miniature structures arranged in a dot pattern. The layout of the components is the same as that shown in FIGS. 7(a) through 7(f), and therefore, this example is described with reference to FIGS. 7(a) through 7(f).

A p-type GaAs substrate 12 having a doping concentration of 10¹⁶ cm⁻³ was prepared. A 0.2-μm thick n⁺-type GaAs layer 11 was formed on the p-type GaAs substrate 12 by MOCVD method.

A 100-nm thick Au—Ge (1%) layer was then formed on the bottom face of the p-type GaAs substrate by a vapor deposition technique. After the formation, the GaAs substrate was annealed for 30 minutes at 450° C. in a nitrogen atmosphere. After the annealing, an electrode 1 having an ohmic contact in the bottom face thereof was formed.

A 3-nm thick SiO₂ film 200 was then formed on the n⁺-type GaAs layer 11 by CVD method.

A 30-nm thick Au layer 101 was then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Au layer formed on the substrate surface at 3000 rpm for 30 seconds, and was then heated on a hot plate at 110° C. for 90 seconds to evaporate the solvent (FIG. 7(b)). The film thickness of the resist 300 was 120 nm. A quartz mold (formed in an area of 9 cm²) 310 having concave portions that were 60 nm in size and were 100 nm in height was prepared. Imprint was then performed by pushing the convex portions of the quartz mold 310 against the resist with a pressure of 10 MPa while the substrate with the resist 300 was being heated at 120° C. (FIG. 7(c)). After the imprint, the substrate was cooled to room temperature, and the quartz mold 310 was released (FIG. 7(d)). After the imprint, concave portions that were arranged in a dot pattern, were 60 nm in size, and were 70 nm in depth were formed in the resist 300.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist 300 were removed, and the Au layer 101 was exposed (FIG. 7(e)).

With the use of an ion milling device, the Au layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, a GaAs solar cell having dots was completed (FIG. 7(f)).

For comparison, a GaAs solar cell that had dots but did not have an SiO₂ film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the GaAs solar cell with a 3-nm SiO₂ film and dots had a preferred value of 10.5%. On the other hand, the photoelectric conversion efficiency of the GaAs solar cell that had dots but did not have an SiO₂ film was 8.5%.

### Example 32

### Dots+SiON Thin Film

This example differs from Example 28 in that the microscopic structures are miniature structures arranged in a dot pattern, and a SiON thin film is used as the wavelength converting layer. The layout of the components is the same as that shown in FIGS. 7(a) through 7(f), and therefore, this example is described with reference to FIGS. 7(a) through 7(f).

A p-type GaAs substrate 12 having a doping concentration of 10¹⁶ cm⁻³ was prepared. A 0.2-μm thick n⁺-type GaAs layer 11 was formed on the p-type GaAs substrate by MOCVD method.

A 100-nm thick Au—Ge (1%) layer was then formed on the bottom face of the p-type GaAs substrate by a vapor deposition technique. After the formation, the GaAs substrate was annealed for 30 minutes at 450° C. in a nitrogen atmosphere. After the annealing, an electrode 1 having an ohmic contact in the bottom face thereof was formed.

A 4-nm thick SiON film 200 was then formed on the n⁺-type GaAs layer by CVD method.

A 30-nm thick Ag layer 101 was then formed on the substrate surface by a vapor deposition technique (FIG. 7(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 3000 rpm for 30 seconds, and was then heated on a hot plate at 110° C. for 90 seconds to evaporate the solvent (FIG. 7(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 7(c)). After the imprint, the substrate was cooled to room temperature, and the quartz mold 310 was released (FIG. 7(d)). After the imprint, concave portions that were arranged in a dot pattern, were 60 nm in size, and were 70 nm in depth were formed in the resist 300.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist 300 were removed, and the Ag layer 101 was exposed (FIG. 7(e)).

With the use of an ion milling device, the Ag layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a GaAs solar cell having dots was completed (FIG. 7(f)).

For comparison, a GaAs solar cell that had dots but did not have an SiON film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the GaAs solar cell with a 4-nm SiON film and dots had a preferred value of 10.3%. On the other hand, the photoelectric conversion efficiency of the GaAs solar cell that had dots but did not have an SiON film was 8.5%.

### Example 33

### Nano-Mesh+SiN Structures

This example differs from Example 28 in that pillar-like SiN structures are used as the wavelength converting layer. The layout of the components is the same as that shown in FIGS. 5(a) through 6(f), and therefore, this example is described with reference to FIGS. 5(a) through 6(f).

A p-type GaAs substrate 12 having a doping concentration of 10¹⁶ cm⁻³ was prepared. A 0.2-μm thick n⁺-type GaAs layer 11 was formed on the p-type GaAs substrate by MOCVD method.

A 100-nm thick Au—Ge (1%) layer was then formed on the bottom face of the p-type GaAs substrate by a vapor deposition technique. After the formation, the GaAs substrate was annealed for 30 minutes at 450° C. in a nitrogen atmosphere. After the annealing, an electrode 1 having an ohmic contact in the bottom face thereof was formed.

A solution formed by diluting an organic SOG composition (OCD-T7 5500-T (a trade name), manufactured by Tokyo Ohka Kogyo Co., Ltd.) with EL at 1:1 was spin-coated on the n⁺-type GaAs layer at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG 500. The film thickness after the hardening was 50 nm.

A solution formed by dissolving 2 wt % of a polymer having a PMMA (Mw: 1500) mixed with a block polymer of a PS (Mw: 58000) and a PMMA (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 80 nm.

The film was annealed for 4 hours at 210° C. in a nitrogen atmosphere, and a phase separation between the PS and the PMMA was performed to form a polystyrene dot pattern of approximately 70 nm in diameter (FIG. 5(a)).

After that, the film was etched by RIE for 15 seconds at an O₂ flow rate of 30 sccm, at a pressure of 13.3 Pa (100 mTorr), and with a power of 100 W. Through the RIE, the PMMA of the phase-separated PS-PMMA was selectively removed to form a PS dot pattern (FIG. 5(b)).

With the PS dot pattern using as a mask, a SOG dot pattern was formed by RIE for 90 seconds at a CF₄ flow rate of 30 sccm, at a pressure of 1.33 Pa (10 mTorr), and with a power of 100 W (FIG. 5(c)).

With the SOG dot pattern using as a mask, GaAs was etched by RIE for 60 seconds at a Cl₂ flow rate of 15 sccm, at an Ar flow rate of 15 sccm, and with an RF power of 100 W. After the RIE using the chlorine gas, a pillar pattern that was 40 nm in size and was 25 nm in height was formed in the n⁺-type GaAs layer (FIG. 5(d)).

A SiN film 203 was then formed by ALD method on the n⁺-type GaAs layer 11 having the pillar pattern formed therein, and the Si pillar pattern was filled with SiN (FIG. 5(e)).

To remove the SiN portions formed on the filled n⁺-type GaAs layer, the SiN was etched by RIE for 30 seconds at a CF₄ flow rate of 30 sccm, at a pressure of 1.33 Pa (10 mTorr), and with a power of 100 W, and the n⁺-type GaAs layer was exposed. Through the above procedures, SiN microscopic structures were formed in the n⁺-type GaAs layer (FIG. 5(f)).

A 30-nm thick Au layer 101 was then formed on the substrate surface by a vapor deposition technique (FIG. 6(a)).

A solution formed by diluting a resist (THMR IP3250, manufactured by Tokyo Ohka Kogyo Co., Ltd.) with ethyl lactate (EL) at 1:2 was spin-coated on the Au layer formed on the substrate surface at 2000 rpm for 30 seconds, and was then heated on a hot plate at 110° C. for 90 seconds to evaporate the solvent (FIG. 6(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist 300 was being heated at 120° C. (FIG. 6(c)). After the imprint, the substrate was cooled to room temperature, and the quartz mold 310 was released (FIG. 6(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Au layer was exposed (FIG. 6(e)).

With the use of an ion milling device, the Au layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, a GaAs solar cell having a nano-mesh metal was completed (FIG. 6(f)).

For comparison, a GaAs solar cell that had a nano-mesh metal but did not have an SiN microscopic structure was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the GaAs solar cell with an SiN microscopic structure and a nano-mesh metal had a preferred value of 9.6%. On the other hand, the photoelectric conversion efficiency of the GaAs solar cell that had nano-mesh metal but did not have an SiN microscopic structure was 8.5%.

### Example 34

### Dots+SiO₂ Structures

This example differs from Example 28 in that pillar-like SiO₂ structures are used as the wavelength converting layer, and dot-like structures spreading in a plane perpendicular to the stacking direction are used as the electrode. The layout of the components is the same as that shown in FIGS. 5(a) through 6(f), and therefore, this example is described with reference to FIGS. 5(a) through 6(f).

A p-type GaAs substrate 12 having a doping concentration of 10¹⁶ cm⁻³ was prepared. A 0.2-μm thick n⁺-type GaAs layer 11 was formed on the p-type GaAs substrate 12 by MOCVD method.

A 100-nm thick Au—Ge (1%) layer was then formed on the bottom face of the p-type GaAs substrate 12 by a vapor deposition technique. After the formation, the GaAs substrate was annealed for 30 minutes at 450° C. in a nitrogen atmosphere. After the annealing, an electrode 1 having an ohmic contact in the bottom face thereof was formed.

A solution formed by diluting an organic SOG composition (OCD-T7 5500-T (a trade name), manufactured by Tokyo Ohka Kogyo Co., Ltd.) with EL at 1:1 was spin-coated on the n⁺-type GaAs layer at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG 500. The film thickness after the hardening was 50 nm.

A solution formed by dissolving 2 wt % of a polymer having a PMMA (Mw: 1500) mixed with a block polymer of a PS (Mw: 58000) and a PMMA (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 80 nm.

The film was annealed for 4 hours at 210° C. in a nitrogen atmosphere, and a phase separation between the PS and the PMMA was performed to form a polystyrene dot pattern of approximately 70 nm in diameter (FIG. 5(a)).

After that, the film was etched by RIE for 15 seconds at an O₂ flow rate of 30 sccm, at a pressure of 13.3 Pa (100 mTorr), and with a power of 100 W. Through the RIE, the PMMA of the phase-separated PS-PMMA was selectively removed to form a PS dot pattern (FIG. 5(b)).

With the PS dot pattern using as a mask, a SOG dot pattern was formed by performing 90-second etching at a CF₄ flow rate of 30 sccm, at a pressure of 1.33 Pa (10 mTorr), and with a power of 100 W (FIG. 5(c)).

With the SOG dot pattern using as a mask, GaAs was etched by RIE for 60 seconds at a Cl₂ flow rate of 15 sccm, at an Ar flow rate of 15 sccm, and with an RF power of 100 W. After the RIE using the chlorine gas, a pillar pattern that was 40 nm in size and was 25 nm in height was formed in the n⁺-layer (FIG. 5(d)).

A SiO₂ film 203 was then formed by ALD method on the n⁺-layer having the pillar pattern formed therein, and the Si pillar pattern was filled with SiO₂ (FIG. 5(e)).

To remove the SiO₂ portions formed on the filled n⁺-type GaAs layer, the SiO₂ was etched by RIE for 30 seconds at a CF₄ flow rate of 30 sccm, at a pressure of 1.33 Pa (10 mTorr), and with a power of 100 W, and the n⁺-type GaAs layer was exposed. Through the above procedures, SiO₂ microscopic structures were formed in the n⁺-type GaAs layer (FIG. 5(f)).

A 30-nm thick Ag layer was then formed on the substrate surface by a vapor deposition technique (FIG. 6(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 3000 rpm for 30 seconds, and was then heated on a hot plate at 110° C. for 90 seconds to evaporate the solvent (FIG. 6(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 6(c)). After the imprint, the substrate was cooled to room temperature, and the quartz mold 310 was released (FIG. 6(d)). After the imprint, concave portions that were arranged in a dot pattern, were 60 nm in size, and were 70 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer was exposed (FIG. 6(e)).

With the use of an ion milling device, the Ag layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a GaAs solar cell having dots was completed (FIG. 6(f)).

For comparison, a GaAs solar cell that had dots but did not have an SiO₂ microscopic structure was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the GaAs solar cell with an SiO₂ microscopic structure and dots had a preferred value of 9.7%. On the other hand, the photoelectric conversion efficiency of the GaAs solar cell that had dots but did not have an SiO₂ microscopic structure was 8.5%.

### Example 35

### Nano-Mesh+SiO₂ Thin Film

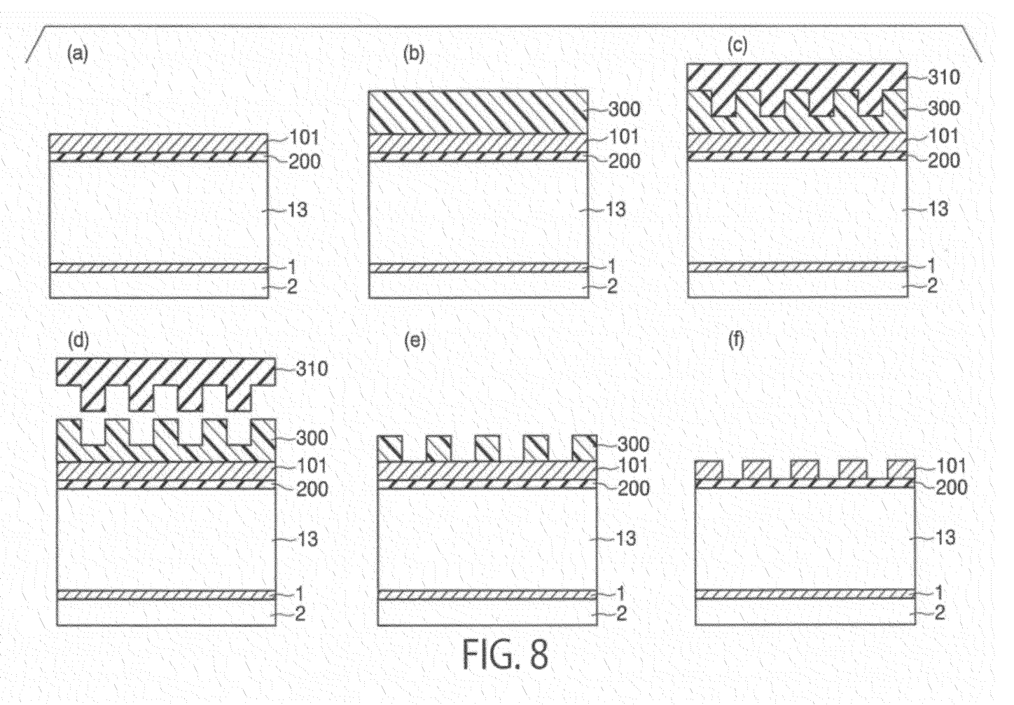

In the following example, CIGS is used for the semiconductor layer. A solar cell of this example is described with reference to FIGS. 8(a) through 8(f).

A Mo electrode 1 to be the lower electrode was formed by a vacuum vapor deposition technique on a substrate 2 made of soda-lime glass. Sputtering was then performed so that Cu, In, and Ga were adhered onto the Mo electrode 1, and a precursor layer was formed. After that, annealing was performed at 500° C. in an atmosphere of a H₂Se gas to form a CIGS layer 13.

A 2-nm thick SiO₂ film 200 was then formed on the CIGS layer 13 by CVD method.

A 30-nm thick Ag layer 101 was then formed on the substrate surface by a vapor deposition technique (FIG. 8(a)).

A solution formed by diluting a resist 300 (THMR IP3250, manufactured by Tokyo Ohka Kogyo Co., Ltd.) with ethyl lactate (EL) at 1:2 was spin-coated on the Ag layer 101 formed on the substrate surface at 2000 rpm for 30 seconds, and was then heated on a hot plate at 110° C. for 90 seconds to evaporate the solvent (FIG. 8(b)). The film thickness of the resist 300 was 150 nm. A quartz mold 310 (formed in an area of 9 cm²) having convex portions that were arranged at a pitch of 150 nm, were 100 nm in size, and were 150 nm in height was prepared. Imprint was then performed by pushing the convex portions of the quartz mold 310 against the resist 300 with a pressure of 10 MPa while the substrate with the resist was being heated at 120° C. (FIG. 8(c)). After the imprint, the substrate was cooled to room temperature, and the quartz mold 310 was released (FIG. 8(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer 101 was exposed (FIG. 7(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent.

A surface electrode was formed by manufacturing a comb-like electrode by a screen printing technique using an Ag paste including an epoxy-based thermosetting resin. In this manner, a CIGS solar cell having a nano-mesh metal was completed (FIG. 7(f)).

For comparison, a CIGS solar cell that had a nano-mesh metal but did not have an SiO₂ film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CIGS solar cell with an SiO₂ film and a nano-mesh metal had a preferred value of 7.0%. On the other hand, the photoelectric conversion efficiency of the CIGS solar cell that had a nano-mesh metal but did not have an SiO₂ film was 6.0%.

As can be seen from the results, in the CIGS solar cell, the photoelectric conversion efficiency became higher as the peak wavelength of electric field enhancement shifted toward the shorter-wavelength side by virtue of the insertion of an SiO₂ film.

### Example 36

### Nano-Mesh+SiN Thin Film

This example differs from Example 35 in that a SiN thin film is used as the wavelength converting layer. A solar cell of this example is described with reference to FIGS. 8(a) through 8(f).

A Mo electrode 1 to be the lower electrode was formed by a vacuum vapor deposition technique on a substrate 2 made of soda-lime glass. Sputtering was then performed so that Cu, In, and Ga were adhered onto the Mo electrode, and a precursor layer was formed. After that, annealing was performed at 500° C. in an atmosphere of a H₂Se gas to form a CIGS layer.

A 2-nm thick SiN film 200 was then formed on the CIGS layer by CVD method.

A 30-nm thick Ag layer 101 was then formed on the substrate surface by a vapor deposition technique (FIG. 8(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 2000 rpm for 30 seconds, and was then heated on a hot plate at 110° C. for 90 seconds to evaporate the solvent (FIG. 8(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist 300 was being heated at 120° C. (FIG. 8(c)). After the imprint, the substrate was cooled to room temperature, and the quartz mold 310 was released (FIG. 8(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer 101 was exposed (FIG. 8(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent (FIG. 8(f)).

A surface electrode was formed by manufacturing a comb-like electrode by a screen printing technique using an Ag paste including an epoxy-based thermosetting resin. In this manner, a CIGS solar cell having a nano-mesh metal was completed (FIG. 8(g)).

For comparison, a CIGS solar cell that had a nano-mesh metal but did not have an SiN film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CIGS solar cell with an SiN film and a nano-mesh metal had a preferred value of 6.7%. On the other hand, the photoelectric conversion efficiency of the CIGS solar cell that had a nano-mesh metal but did not have an SiN film was 6.0%.

As can be seen from the results, in the CIGS solar cell, the photoelectric conversion efficiency became higher as the peak wavelength of electric field enhancement shifted toward the shorter-wavelength side by virtue of the insertion of an SiN film.

### Example 37

### Nano-Mesh+SiON Thin Film

This example differs from Example 35 in that a SiON thin film is used as the wavelength converting layer. A solar cell of this example is described with reference to FIGS. 8(a) through 8(f).

A Mo electrode 1 to be the lower electrode was formed by a vacuum vapor deposition technique on a substrate 2 made of soda-lime glass. Sputtering was then performed so that Cu, In, and Ga were adhered onto the Mo electrode 1, and a precursor layer was formed. After that, annealing was performed at 500° C. in an atmosphere of an H₂Se gas to form a CIGS layer 13.

A 2-nm thick SiON film 200 was then formed on the CIGS layer 13 by CVD method.

A 30-nm thick Au layer 101 was then formed on the substrate surface by a vapor deposition technique (FIG. 8(a)).

A solution formed by diluting a resist (THMR IP3250, manufactured by Tokyo Ohka Kogyo Co., Ltd.) with ethyl lactate (EL) at 1:2 was spin-coated on the Au layer 101 formed on the substrate surface at 2000 rpm for 30 seconds, and was then heated on a hot plate at 110° C. for 90 seconds to evaporate the solvent (FIG. 8(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist 300 was being heated at 120° C. (FIG. 8(c)). After the imprint, the substrate was cooled to room temperature, and the quartz mold 310 was released (FIG. 8(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Au layer 101 was exposed (FIG. 8(e)).

With the use of an ion milling device, the Au layer 101 was etched by the ion milling for 90 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Au layer 101. The remaining portions of the resist were removed with an organic solvent (FIG. 8(f)).

A surface electrode was formed by manufacturing a comb-like electrode by a screen printing technique using an Ag paste including an epoxy-based thermosetting resin. In this manner, a CIGS solar cell having a nano-mesh metal was completed (FIG. 8(g)).

For comparison, a CIGS solar cell that had a nano-mesh metal but did not have an SiON film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CIGS solar cell with a 3-nm SiON film and a nano-mesh metal had a preferred value of 6.9%. On the other hand, the photoelectric conversion efficiency of the CIGS solar cell that had nano-mesh metal but did not have an SiON film was 6.0%.

As can be seen from the results, in the CIGS solar cell, the photoelectric conversion efficiency became higher as the peak wavelength of electric field enhancement shifted toward the shorter-wavelength side by virtue of the insertion of an SiON film.

### Example 38

### Dots+SiO₂ Thin Film

This example differs from Example 35 in that the microscopic structures are miniature structures arranged in a dot pattern spreading in a plane perpendicular to the stacking direction. A solar cell of this example is described with reference to FIGS. 8(a) through 8(f).

A Mo electrode 1 to be the lower electrode was formed by a vacuum vapor deposition technique on a substrate 2 made of soda-lime glass. Sputtering was then performed so that Cu, In, and Ga were adhered onto the Mo electrode, and a precursor layer was formed. After that, annealing was performed at 500° C. in an atmosphere of an H₂Se gas to form a CIGS layer 13.

A 2-nm thick SiO₂ film 200 was then formed on the CIGS layer 13 by CVD method.

A 30-nm thick Au layer 101 was then formed on the substrate surface by a vapor deposition technique (FIG. 8(a)).

A solution formed by diluting a resist (THMR IP3250, manufactured by Tokyo Ohka Kogyo Co., Ltd.) with ethyl lactate (EL) at 1:2 was spin-coated on the Au layer formed on the substrate surface at 3000 rpm for 30 seconds, and was then heated on a hot plate at 110° C. for 90 seconds to evaporate the solvent (FIG. 8(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 8(c)). After the imprint, the substrate was cooled to room temperature, and the quartz mold 310 was released (FIG. 8(d)). After the imprint, concave portions that were arranged in a dot pattern, were 60 nm in size, and were 70 nm in depth were formed in the resist 300.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist were removed, and the Au layer 101 was exposed (FIG. 8(e)).

With the use of an ion milling device, the Au layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Au layer 101. The remaining portions of the resist were removed with an organic solvent (FIG. 8(f)).

A 70-nm CdS layer was formed on the Au dots. A ZnO layer was formed on the CdS layer as a transparent electrode film by MOCVD method.

A surface electrode was formed by manufacturing a comb-like electrode by a screen printing technique using an Ag paste including an epoxy-based thermosetting resin. In this manner, a CIGS solar cell having dots was completed (FIG. 8(g)).

For comparison, a CIGS solar cell that had dots but did not have an SiO₂ film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CIGS solar cell with a 3-nm SiO₂ film and dots had a preferred value of 7.5%. On the other hand, the photoelectric conversion efficiency of the CIGS solar cell that had dots but did not have an SiO₂ film was 6.5%.

### Example 39

### Dots+SiON Thin Film

This example differs from Example 35 in that the microscopic structures are miniature structures arranged in a dot pattern spreading in a plane perpendicular to the stacking direction, and a SiON thin film is used as the wavelength converting layer. A solar cell of this example is described with reference to FIGS. 8(a) through 8(f).

A Mo electrode 1 to be the lower electrode was formed by a vacuum vapor deposition technique on a substrate 2 made of soda-lime glass. Sputtering was then performed so that Cu, In, and Ga were adhered onto the Mo electrode 1 and a precursor layer was formed. After that, annealing was performed at 500° C. in an atmosphere of an H₂Se gas to form a CIGS layer 13.

A 4-nm thick SiON film 200 was then formed on the CIGS layer 13 by CVD method.

A 30-nm thick Ag layer 101 was then formed on the substrate surface by a vapor deposition technique (FIG. 8(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 3000 rpm for 30 seconds, and was then heated on a hot plate at 110° C. for 90 seconds to evaporate the solvent (FIG. 8(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 8(c)). After the imprint, the substrate was cooled to room temperature, and the quartz mold 310 was released (FIG. 8(d)). After the imprint, concave portions that were arranged in a dot pattern, were 60 nm in size, and were 70 nm in depth were formed in the resist 300.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist were removed, and the Ag layer 101 was exposed (FIG. 8(e)).

With the use of an ion milling device, the Ag layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Ag layer 101. The remaining portions of the resist were removed with an organic solvent (FIG. 8(f)).

A 70-nm CdS layer was formed on the Ag dots. A ZnO layer was formed on the CdS layer as a transparent electrode film by MOCVD method.

A surface electrode was formed by manufacturing a comb-like electrode by a screen printing technique using an Ag paste including an epoxy-based thermosetting resin. In this manner, a CIGS solar cell having dots was completed (FIG. 8(g)).

For comparison, a CIGS solar cell that had dots but did not have an SiON film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CIGS solar cell with a 4-nm SiON film and dots had a preferred value of 7.3%. On the other hand, the photoelectric conversion efficiency of the CIGS solar cell that had dots but did not have an SiON film was 6.5%.

### Example 40

### Nano-Mesh+SiN Structures

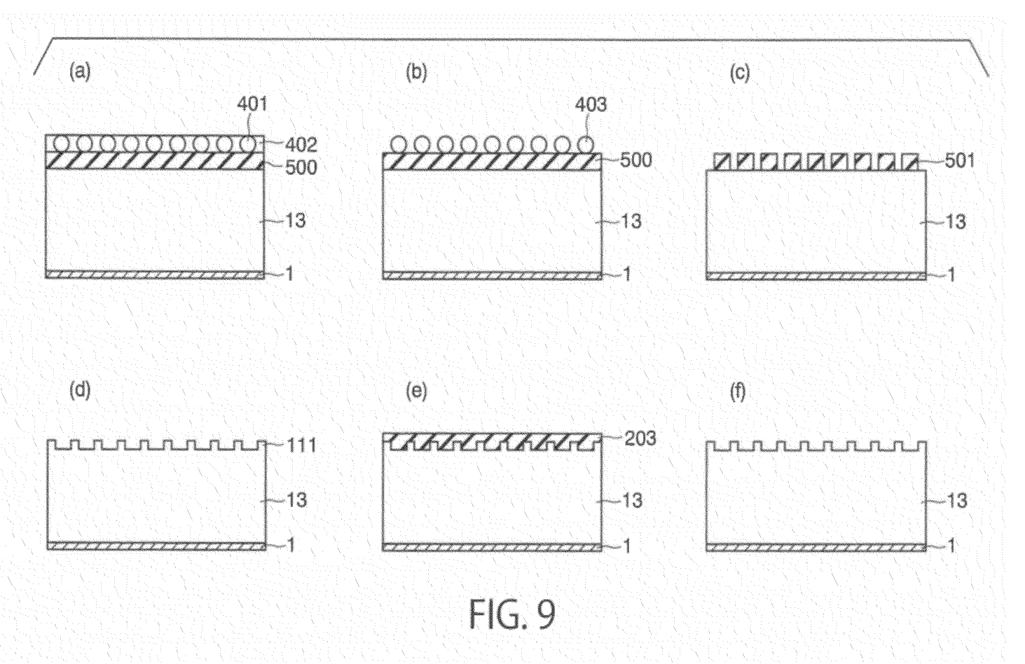

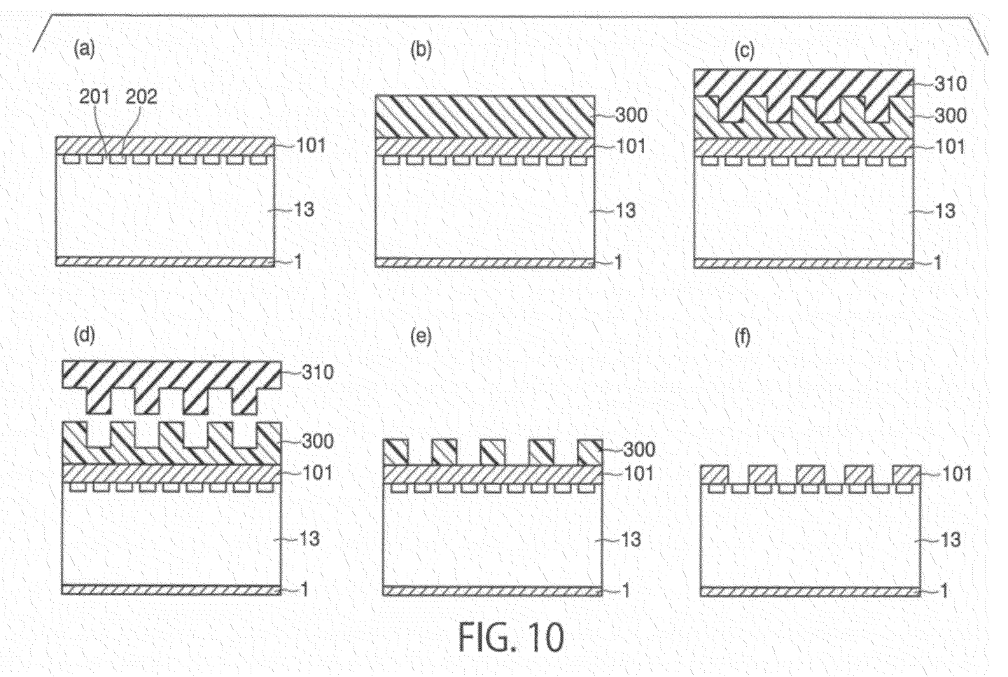

This example differs from Example 35 in that pillar-like SiN structures are used as the wavelength converting layer. A solar cell of this example is described with reference to FIGS. 9(a) through 10(f).

A Mo electrode 1 to be the lower electrode was formed by a vacuum vapor deposition technique on a substrate 2 made of soda-lime glass. Sputtering was then performed so that Cu, In, and Ga were adhered onto the Mo electrode, and a precursor layer was formed. After that, annealing was performed at 500° C. in an atmosphere of a H₂Se gas to form a CIGS layer 13.

A solution formed by diluting an organic SOG composition 500 (OCD-T7 5500-T (a trade name), manufactured by Tokyo Ohka Kogyo Co., Ltd.) with EL at 1:1 was spin-coated on the CIGS layer 13 at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG. The film thickness after the hardening was 50 nm.

A solution formed by dissolving 2 wt % of a polymer having a PMMA 402 (Mw: 1500) mixed with a block polymer of a PS 401 (Mw: 58000) and a PMMA 402 (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 80 nm.

The film was annealed for 4 hours at 210° C. in a nitrogen atmosphere, and a phase separation between the PS 401 and the PMMA 402 was performed to form a polystyrene dot pattern of approximately 70 nm in diameter (FIG. 9(a)).

After that, the film was etched by RIE for 15 seconds at an O₂ flow rate of 30 sccm, at a pressure of 13.3 Pa (100 mTorr), and with a power of 100 W. Through the RIE, the PMMA of the phase-separated PS-PMMA was selectively removed to form a PS dot pattern 403 (FIG. 9(b)).

With the PS dot pattern 403 using as a mask, a SOG dot pattern 501 was formed by RIE for 90 seconds at a CF₄ flow rate of 30 sccm, at a pressure of 1.33 Pa (10 mTorr), and with a power of 100 W (FIG. 9(c)).

With the SOG dot pattern 501 using as a mask, CIGS was etched by RIE for 60 seconds at a Cl₂ flow rate of 15 sccm, at an Ar flow rate of 15 sccm, and with an RF power of 100 W. After the RIE using the chlorine gas, a pillar pattern 111 that was 40 nm in size and was 20 nm in height was formed in the CIGS layer (FIG. 9(d)).

A SiN film was then formed by ALD method on the CIGS layer having the pillar pattern formed therein, and the Si pillar pattern was filled with SiN 203 (FIG. 9(e)).

To remove the SiN portions formed on the filled CIGS layer, the SiN was etched by RIE for 30 seconds at a CF₄ flow rate of 30 sccm, at a pressure of 1.33 Pa (10 mTorr), and with a power of 100 W, and the CIGS layer was exposed. Through the above procedures, SiN microscopic structures were formed in the CIGS layer (FIG. 9(f)).

A 30-nm thick Au layer 101 was then formed on the substrate surface by a vapor deposition technique (FIG. 10(a)).

A solution formed by diluting a resist 300 (THMR IP3250, manufactured by Tokyo Ohka Kogyo Co., Ltd.) with ethyl lactate (EL) at 1:2 was spin-coated on the Au layer 101 formed on the substrate surface at 2000 rpm for 30 seconds, and was then heated on a hot plate at 110° C. for 90 seconds to evaporate the solvent (FIG. 10(b)). The film thickness of the resist 300 was 150 nm. A quartz mold 310 (formed in an area of 9 cm²) having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist was being heated at 120° C. (FIG. 10(c)).

After the imprint, the substrate was cooled to room temperature, and the quartz mold 310 was released (FIG. 10(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Au layer 101 was exposed (FIG. 10(e)).

With the use of an ion milling device, the Au layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, a CIGS solar cell having a nano-mesh metal was completed (FIG. 10(f)).

For comparison, a CIGS solar cell that had a nano-mesh metal but did not have an SiN microscopic structure was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CIGS solar cell with an SiN microscopic structure and a nano-mesh metal had a preferred value of 6.8%. On the other hand, the photoelectric conversion efficiency of the CIGS solar cell that had nano-mesh metal but did not have an SiN microscopic structure was 6.0%.

### Example 41

### Dots+SiO₂ Structures

This example differs from Example 35 in that the microscopic structures are miniature structures arranged in a dot pattern, and pillar-like SiO₂ structures are used as the wavelength converting layer. A solar cell of this example is described with reference to FIGS. 9(a) through 10(f).

A Mo electrode 1 to be the lower electrode was formed by a vacuum vapor deposition technique on a substrate 2 made of soda-lime glass. Sputtering was then performed so that Cu, In, and Ga were adhered onto the Mo electrode 1, and a precursor layer was formed. After that, annealing was performed at 500° C. in an atmosphere of an H₂Se gas to form a CIGS layer 13.

A solution formed by diluting an organic SOG composition (OCD-T7 5500-T (a trade name), manufactured by Tokyo Ohka Kogyo Co., Ltd.) with EL at 1:1 was spin-coated on the CIGS layer at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG. The film thickness after the hardening was 50 nm.

A solution formed by dissolving 2 wt % of a polymer having a PMMA (Mw: 1500) mixed with a block polymer of a PS (Mw: 58000) and a PMMA (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 80 nm.

The film was annealed for 4 hours at 210° C. in a nitrogen atmosphere, and a phase separation between the PS and the PMMA was performed to form a polystyrene dot pattern of approximately 70 nm in diameter (FIG. 9(a)).

After that, the film was etched by RIE for 15 seconds at an O₂ flow rate of 30 sccm, at a pressure of 13.3 Pa (100 mTorr), and with a power of 100 W. Through the RIE, the PMMA of the phase-separated PS-PMMA was selectively removed to form a PS dot pattern (FIG. 9(b)).

With the PS dot pattern using as a mask, a SOG dot pattern was formed by RIE for 90 seconds at a CF₄ flow rate of 30 sccm, at a pressure of 1.33 Pa (10 mTorr), and with a power of 100 W (FIG. 9(c)).

With the SOG dot pattern using as a mask, CIGS was etched by RIE for 60 seconds at a Cl₂ flow rate of 15 sccm, at an Ar flow rate of 15 sccm, and with an RF power of 100 W. After the RIE using the chlorine gas, a pillar pattern that was 40 nm in size and was 20 nm in height was formed in the CIGS layer (FIG. 9(d)).

A SiO₂ film 203 was then formed by ALD method on the CIGS layer having the pillar pattern formed therein, and the Si pillar pattern was filled with SiO₂ (FIG. 9(e)).

To remove the SiO₂ portions formed on the filled CIGS layer, the SiO₂ was etched by RIE for 30 seconds at a CF₄ flow rate of 30 sccm, at a pressure of 1.33 Pa (10 mTorr), and with a power of 100 W, and the CIGS layer was exposed. Through the above procedures, SiO₂ microscopic structures were formed in the CIGS layer (FIG. 9(f)).

A 30-nm thick Ag layer 101 was then formed on the substrate surface by a vapor deposition technique (FIG. 10(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 3000 rpm for 30 seconds, and was then heated on a hot plate at 110° C. for 90 seconds to evaporate the solvent (FIG. 10(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 10(c)). After the imprint, the substrate was cooled to room temperature, and the quartz mold 310 was released (FIG. 10(d)). After the imprint, concave portions that were arranged in a dot pattern, were 60 nm in size, and were 70 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer 101 was exposed (FIG. 10(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a dot pattern that was 60 nm in size was formed in the Ag layer 101. The remaining portions of the resist were removed with an organic solvent.

A 70-nm CdS layer was formed on the Au dots. A ZnO layer was formed on the CdS layer as a transparent electrode film by MOCVD method.

A surface electrode was formed by manufacturing a comb-like electrode by a screen printing technique using an Ag paste including an epoxy-based thermosetting resin. In this manner, a CIGS solar cell having dots was completed (FIG. 10(f)).

For comparison, a CIGS solar cell that had dots but did not have an SiO₂ microscopic structure was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CIGS solar cell with an SiO₂ microscopic structure and a dots had a preferred value of 7.2%. On the other hand, the photoelectric conversion efficiency of the CIGS solar cell that had dots but did not have an SiO₂ microscopic structure was 6.5%.

### Example 42

### Nano-Mesh+SiO₂ Thin Film

The following example concerns a solar cell using CdTe for the semiconductor layer. The layout of the components is the same as that shown in FIGS. 8(a) through 8(f), and therefore, this example is described with reference to FIGS. 8(a) through 8(f).

A CdTe layer 13 was formed by a close spaced sublimation method on a substrate 2 made of graphite.

A 2-nm thick SiO₂ film 200 was then formed on the CdTe layer 13 by CVD method.

A 30-nm thick Ag layer 101 was then formed on the substrate surface by a vapor deposition technique (FIG. 8(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 2000 rpm for 30 seconds, and was then heated on a hot plate at 110° C. for 90 seconds to evaporate the solvent (FIG. 8(b)). The film thickness of the resist 300 was 150 nm. A quartz mold (formed in an area of 9 cm²) 310 having convex portions that were arranged at a pitch of 150 nm, were 100 nm in size, and were 150 nm in height was prepared. Imprint was then performed by pushing the convex portions of the quartz mold 310 against the resist 300 with a pressure of 10 MPa while the substrate with the resist 300 was being heated at 120° C. (FIG. 8(c)). After the imprint, the substrate was cooled to room temperature, and the quartz mold 310 was released (FIG. 8(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer 101 was exposed (FIG. 8(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent (FIG. 8(f)).

A surface electrode was formed by manufacturing a comb-like electrode by a screen printing technique using an Ag paste including an epoxy-based thermosetting resin. In this manner, a CdTe solar cell having a nano-mesh metal was completed (FIG. 8(g)).

For comparison, a CdTe solar cell that had a nano-mesh metal but did not have an SiO₂ film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CdTe solar cell with a 2-nm SiO₂ film and a nano-mesh metal had a preferred value of 9.0%. On the other hand, the photoelectric conversion efficiency of the CdTe solar cell that had the a nano-mesh metal but did not have an SiO₂ film was 8.0%.

As can be seen from the results, in the CdTe solar cell, the photoelectric conversion efficiency became higher as the peak wavelength of electric field enhancement shifted toward the shorter-wavelength side by virtue of the insertion of an SiO₂ film.

### Example 43

### Nano-Mesh+SiN Thin Film

This example differs from Example 42 in that a SiN thin film is used as the wavelength converting layer. The layout of the components is the same as that shown in FIGS. 8(a) through 8(f), and therefore, this example is described with reference to FIGS. 8(a) through 8(f).

A CdTe layer 13 was formed by a close spaced sublimation method on a substrate 1, 2 made of graphite.

A 2-nm thick SiN film 200 was then formed on the CdTe layer by CVD method.

A 30-nm thick Ag layer 101 was then formed on the substrate surface by a vapor deposition technique (FIG. 8(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 2000 rpm for 30 seconds, and was then heated on a hot plate at 110° C. for 90 seconds to evaporate the solvent (FIG. 8(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist 300 was being heated at 120° C. (FIG. 8(c)). After the imprint, the substrate was cooled to room temperature, and the quartz mold 310 was released (FIG. 8(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer 101 was exposed (FIG. 8(e)).

With the use of an ion milling device, the Ag layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent (FIG. 8(f)).

A surface electrode was formed by manufacturing a comb-like electrode by a screen printing technique using an Ag paste including an epoxy-based thermosetting resin. In this manner, a CdTe solar cell having a nano-mesh metal was completed (FIG. 8(g)).

For comparison, a CdTe solar cell that had a nano-mesh metal but did not have an SiN film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CdTe solar cell with a 2-nm SiN film and a nano-mesh metal had a preferred value of 8.8%. On the other hand, the photoelectric conversion efficiency of the CdTe solar cell that had the a nano-mesh metal but did not have an SiN film was 8.0%.

As can be seen from the results, in the CdTe solar cell, the photoelectric conversion efficiency became higher as the peak wavelength of electric field enhancement shifted toward the shorter-wavelength side by virtue of the insertion of an SiN film.

### Example 44

### Nano-Mesh+SiON Thin Film

This example differs from Example 42 in that a SiON thin film is used as the wavelength converting layer. The layout of the components is the same as that shown in FIGS. 8(a) through 8(f), and therefore, this example is described with reference to FIGS. 8(a) through 8(f).

A CdTe layer 13 was formed by a close spaced sublimation method on a substrate 2, 1 made of graphite.

A 2-nm thick SiON film 200 was then formed on the CdTe layer 13 by CVD method.

A 30-nm thick Au layer 101 was then formed on the substrate surface by a vapor deposition technique (FIG. 8(a)).

A solution formed by diluting a resist (THMR IP3250, manufactured by Tokyo Ohka Kogyo Co., Ltd.) with ethyl lactate (EL) at 1:2 was spin-coated on the Au layer formed on the substrate surface at 2000 rpm for 30 seconds, and was then heated on a hot plate at 110° C. for 90 seconds to evaporate the solvent (FIG. 8(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist 300 was being heated at 120° C. (FIG. 8(c)). After the imprint, the substrate was cooled to room temperature, and the quartz mold 310 was released (FIG. 8(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer 101 was exposed (FIG. 8(e)).

With the use of an ion milling device, the Ag layer 101 was etched by the ion milling for 90 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Ag layer 101. The remaining portions of the resist were removed with an organic solvent (FIG. 8(f)).

A surface electrode was formed by manufacturing a comb-like electrode by a screen printing technique using an Ag paste including an epoxy-based thermosetting resin. In this manner, a CdTe solar cell having a nano-mesh metal was completed (FIG. 8(g)).

For comparison, a CdTe solar cell that had a nano-mesh metal but did not have an SiON film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CdTe solar cell with a 3-nm SiON film and a nano-mesh metal had a preferred value of 8.9%. On the other hand, the photoelectric conversion efficiency of the CdTe solar cell that had the a nano-mesh metal but did not have an SiON film was 8.0%.

As can be seen from the results, in the CdTe solar cell, the photoelectric conversion efficiency became higher as the peak wavelength of electric field enhancement shifted toward the shorter-wavelength side by virtue of the insertion of an SiON film.

### Example 45

### Dots+SiO₂ Thin Film

This example differs from Example 42 in that the microscopic structures are miniature structures arranged in a dot pattern, and a SiO₂ thin film is used as the wavelength converting layer. The layout of the components is the same as that shown in FIGS. 8(a) through 8(f), and therefore, this example is described with reference to FIGS. 8(a) through 8(f).

A CdTe layer 13 was formed by a close spaced sublimation method on a substrate 2,1 made of graphite.

A 2-nm thick SiO₂ film 200 was then formed on the CdTe layer 13 by CVD method.

A 30-nm thick Au layer 101 was then formed on the substrate surface by a vapor deposition technique (FIG. 8(a)).

A solution formed by diluting a resist (THMR IP3250, manufactured by Tokyo Ohka Kogyo Co., Ltd.) with ethyl lactate (EL) at 1:2 was spin-coated on the Au layer formed on the substrate surface at 3000 rpm for 30 seconds, and was then heated on a hot plate at 110° C. for 90 seconds to evaporate the solvent (FIG. 8(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 8(c)). After the imprint, the substrate was cooled to room temperature, and the quartz mold 310 was released (FIG. 8(d)). After the imprint, concave portions that were arranged in a dot pattern, were 60 nm in size, and were 70 nm in depth were formed in the resist 300.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist were removed, and the Au layer 101 was exposed (FIG. 8(e)).

With the use of an ion milling device, the Au layer 101 was etched by the ion milling for 80 seconds at an accelerating voltage of 500 V and with an ion current of 40 mA to form a metal electrode layer having openings. Through the ion milling, a dot pattern that was 60 nm in size was formed in the Au layer 101. The remaining portions of the resist were removed with an organic solvent (FIG. 8(f)).

A 70-nm CdS layer was formed on the Au dots. A ZnO layer was formed on the CdS layer as a transparent electrode film by MOCVD method.

A surface electrode was formed by manufacturing a comb-like electrode by a screen printing technique using an Ag paste including an epoxy-based thermosetting resin. In this manner, a CdTe solar cell having dots was completed (FIG. 8(g)).

For comparison, a CdTe solar cell that had dots but did not have an SiO₂ film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CdTe solar cell with an SiO₂ film and dots had a preferred value of 9.2%. On the other hand, the photoelectric conversion efficiency of the CdTe solar cell that had dots but did not have an SiO₂ film was 8.0%.

### Example 46

### Dots+SiON Thin Film

This example differs from Example 42 in that the microscopic structures are miniature structures arranged in a dot pattern, and a SiON thin film is used as the wavelength converting layer. The layout of the components is the same as that shown in FIG. 8, and therefore, this example is described with reference to FIGS. 8(a) through 8(f).

A CdTe layer 13 was formed by a close spaced sublimation method on a substrate 2,1 made of graphite.

A 4-nm thick SiON film 200 was then formed on the CdTe layer 13 by CVD method.

A 30-nm thick Ag layer 101 was then formed on the substrate surface by a vapor deposition technique (FIG. 8(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 3000 rpm for 30 seconds, and was then heated on a hot plate at 110° C. for 90 seconds to evaporate the solvent (FIG. 8(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 8(c)). After the imprint, the substrate was cooled to room temperature, and the quartz mold 310 was released (FIG. 8(d)). After the imprint, concave portions that were arranged in a dot pattern, were 60 nm in size, and were 70 nm in depth were formed in the resist 300.

The resist pattern 300 having the concave pattern was etched by RIE at an O₂ flow rate of 30 sccm, at 10 mTorr, and with an RF power of 100 W for 30 seconds. After the RIE using O₂, bottom portions of the resist were removed, and the Ag layer 101 was exposed (FIG. 8(e)).

With the use of an ion milling device, the Ag layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Ag layer 101. The remaining portions of the resist were removed with an organic solvent (FIG. 8(f)).

A 70-nm CdS layer was formed on the Au dots. A ZnO layer was formed on the CdS layer as a transparent electrode film by MOCVD method.

A surface electrode was formed by manufacturing a comb-like electrode by a screen printing technique using an Ag paste including an epoxy-based thermosetting resin. In this manner, a CdTe solar cell having dots was completed (FIG. 8(g)).

For comparison, a CdTe solar cell that had dots but did not have an SiON film was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CdTe solar cell with a 4-nm SiON film and dots had a preferred value of 9.4%. On the other hand, the photoelectric conversion efficiency of the CdTe solar cell that had dots but did not have an SiON film was 8.3%.

### Example 47

### Nano-Mesh+SiN Structures

This example differs from Example 42 in that pillar-like SiN structures are used as the wavelength converting layer. The layout of the components is the same as that shown in FIGS. 9(a) through 10(f), and therefore, this example is described with reference to FIGS. 9(a) through 10(f).

A CdTe layer 13 was formed by a close spaced sublimation method on a substrate 2,1 made of graphite.

A solution formed by diluting an organic SOG composition (OCD-T7 5500-T (a trade name), manufactured by Tokyo Ohka Kogyo Co., Ltd.) with EL at 1:1 was spin-coated on the CdTe layer at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG 500. The film thickness after the hardening was 50 nm.

A solution formed by dissolving 2 wt % of a polymer having a PMMA (Mw: 1500) mixed with a block polymer of a PS (Mw: 58000) and a PMMA (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 80 nm.

The film was annealed for 4 hours at 210° C. in a nitrogen atmosphere, and a phase separation between the PS and the PMMA was performed to form a polystyrene dot pattern of approximately 70 nm in diameter (FIG. 9(a)).

After that, the film was etched by RIE for 15 seconds at an O₂ flow rate of 30 sccm, at a pressure of 13.3 Pa (100 mTorr), and with a power of 100 W. Through the RIE, the PMMA of the phase-separated PS-PMMA was selectively removed to form a PS dot pattern (FIG. 9(b)).

With the PS dot pattern using as a mask, a SOG dot pattern was formed by RIE for 90 seconds at a CF₄ flow rate of 30 sccm, at a pressure of 1.33 Pa (10 mTorr), and with a power of 100 W (FIG. 9(c)).

With the SOG dot pattern using as a mask, CdTe was etched by RIE for 60 seconds at a Cl₂ flow rate of 15 sccm, at an Ar flow rate of 15 sccm, and with an RF power of 100 W. After the RIE using the chlorine gas, a pillar pattern that was 40 nm in size and was 20 nm in height was formed in the CdTe layer (FIG. 9(d)).

A SiN film 203 was then formed by ALD method on the CdTe layer having the pillar pattern formed therein, and the Si pillar pattern was filled with SiN (FIG. 9(e)).

To remove the SiN portions formed on the filled CdTe layer, the SiN was etched by RIE for 30 seconds at a CF₄ flow rate of 30 sccm, at a pressure of 1.33 Pa (10 mTorr), and with a power of 100 W, and the CdTe layer was exposed. Through the above procedures, SiN microscopic structures were formed in the CdTe layer (FIG. 9(f)).

A 30-nm thick Au layer 101 was then formed on the substrate surface by a vapor deposition technique (FIG. 10(a)).

A solution formed by diluting a resist (THMR IP3250, manufactured by Tokyo Ohka Kogyo Co., Ltd.) with ethyl lactate (EL) at 1:2 was spin-coated on the Au layer formed on the substrate surface at 2000 rpm for 30 seconds, and was then heated on a hot plate at 110° C. for 90 seconds to evaporate the solvent (FIG. 10(b)). The film thickness of the resist 300 was 150 nm. A quartz mold (formed in an area of 9 cm²) 310 having convex portions that were arranged at a pitch of 200 nm, were 100 nm in size, and were 150 nm in height was prepared. Imprint was then performed by pushing the convex portions of the quartz mold 310 against the resist 300 with a pressure of 10 MPa while the substrate with the resist 300 was being heated at 120° C. (FIG. 10(c)). After the imprint, the substrate was cooled to room temperature, and the quartz mold 310 was released (FIG. 10(d)). After the imprint, concave portions that were arranged at a pitch of 200 nm, were 100 nm in size, and were 100 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Au layer 101 was exposed (FIG. 10(e)).

With the use of an ion milling device, the Au layer 101 was etched by the ion milling for 80 seconds at an accelerating voltage of 500 V and with an ion current of 40 mA to form a metal electrode layer having openings. Through the ion milling, a pattern with openings that were arranged at a pitch of 200 nm and were 100 nm in size was formed in the Au layer 101. The remaining portions of the resist were removed with an organic solvent.

A surface electrode was formed by manufacturing a comb-like electrode by a screen printing technique using an Ag paste including an epoxy-based thermosetting resin. In this manner, a CdTe solar cell having a nano-mesh was completed (FIG. 10(f)).

For comparison, a CdTe solar cell that had a nano-mesh metal but did not have an SiN microscope structure was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CdTe solar cell with an SiN microscope structure and a nano-mesh metal had a preferred value of 8.8%. On the other hand, the photoelectric conversion efficiency of the CdTe solar cell that had the a nano-mesh metal but did not have an SiN microscope structure was 8.0%.

### Example 48

### Dots+SiO₂ Structures

This example differs from Example 42 in that pillar-like SiO₂ structures are used as the wavelength converting layer. The layout of the components is the same as that shown in FIGS. 9(a) through 10(f), and therefore, this example is described with reference to FIGS. 9(a) through 10(f).

A CdTe layer 13 was formed by a close spaced sublimation method on a substrate 2,1 made of graphite.

A solution formed by diluting an organic SOG composition (OCD-T7 5500-T (a trade name), manufactured by Tokyo Ohka Kogyo Co., Ltd.) with EL at 1:1 was spin-coated on the CdTe layer at 3000 rpm for 30 seconds, and was then heated on a hot plate at 110° C. for 90 seconds to evaporate the solvent. The SOG film 500 was annealed at 250° C. in a nitrogen atmosphere to thermally harden the SOG 500. The film thickness after the hardening was 50 nm.

A solution formed by dissolving 2 wt % of a polymer having a PMMA (Mw: 1500) mixed with a block polymer of a PS (Mw: 58000) and a PMMA (Mw: 130000) at a weight ratio of 6:4 in a propylene glycol monomethyl ether acetate (PGMEA) was applied by a spin coating technique at 2000 rpm for 30 seconds. Prebaking was then performed at 110° C. for 90 seconds to evaporate the solvent and achieve a film thickness of 80 nm.

The film was annealed for 4 hours at 210° C. in a nitrogen atmosphere, and a phase separation between the PS and the PMMA was performed to form a polystyrene dot pattern of approximately 70 nm in diameter (FIG. 9(a)).

After that, the film was etched by RIE for 15 seconds at an O₂ flow rate of 30 sccm, at a pressure of 13.3 Pa (100 mTorr), and with a power of 100 W. Through the RIE, the PMMA of the phase-separated PS-PMMA was selectively removed to form a PS dot pattern (FIG. 9(b)).

With the PS dot pattern using as a mask, a SOG dot pattern was formed by performing 90-second etching at a CF₄ flow rate of 30 sccm, at a pressure of 1.33 Pa (10 mTorr), and with a power of 100 W (FIG. 9(c)).

With the SOG dot pattern using as a mask, CdTe was etched by RIE for 60 seconds at a Cl₂ flow rate of 15 sccm, at an Ar flow rate of 15 sccm, and with an RF power of 100 W. After the RIE using the chlorine gas, a pillar pattern that was 40 nm in size and was 20 nm in height was formed in the CdTe layer (FIG. 9(d)).

A SiO₂ film 200 was then formed by ALD method on the CdTe layer 13 having the pillar pattern formed therein, and the Si pillar pattern was filled with SiO₂ (FIG. 9(e)).

To remove the SiO₂ portions formed on the filled CdTe layer, the SiO₂ was etched by RIE for 30 seconds at a CF₄ flow rate of 30 sccm, at a pressure of 1.33 Pa (10 mTorr), and with a power of 100 W, and the CdTe layer was exposed. Through the above procedures, SiO₂ microscopic structures were formed in the CdTe layer (FIG. 9(f)).

A 30-nm thick Ag layer 101 was then formed on the substrate surface by a vapor deposition technique (FIG. 10(a)).

A solution formed by diluting a resist (THMR IP3250, manufactured by Tokyo Ohka Kogyo Co., Ltd.) with ethyl lactate (EL) at 1:2 was spin-coated on the Ag layer formed on the substrate surface at 3000 rpm for 30 seconds, and was then heated on a hot plate at 110° C. for 90 seconds to evaporate the solvent (FIG. 10(b)). The film thickness of the resist 300 was 120 nm. A quartz mold (formed in an area of 9 cm²) 310 having convex portions that were 60 nm in size and were 100 nm in height was prepared. Imprint was then performed by pushing the convex portions of the quartz mold 310 against the resist 300 with a pressure of 10 MPa while the substrate with the resist 300 was being heated at 120° C. (FIG. 10(c)). After the imprint, the substrate was cooled to room temperature, and the quartz mold 310 was released (FIG. 10(d)). After the imprint, concave portions that were arranged in a dot pattern, were 60 nm in size, and were 70 nm in depth were formed in the resist 300.

The resist pattern 300 having the concave pattern was etched by RIE at a CF₄ flow rate of 30 sccm, at 10 mTorr, and with an RF power of 100 W for 30 seconds. After the RIE using CF₄, bottom portions of the resist were removed, and the Ag layer 101 was exposed (FIG. 10(e)).

With the use of an ion milling device, the Ag layer 101 was etched by the ion milling for 60 seconds at an accelerating voltage of 500 V and with an ion current of 40 mA to form a metal electrode layer having openings. Through the ion milling, a dot pattern that was 60 nm in size was formed in the Ag layer 101. The remaining portions of the resist were removed with an organic solvent (FIG. 10(f)).

A 70-nm CdS layer was formed on the Au dots. A ZnO layer was formed on the CdS layer as a transparent electrode film by MOCVD method.

A surface electrode was formed by manufacturing a comb-like electrode by a screen printing technique using an Ag paste including an epoxy-based thermosetting resin. In this manner, a CdTe solar cell having dots was completed (FIG. 8(g)).

For comparison, a CdTe solar cell that had dots but did not have an SiO₂ microscope structure was also manufactured in the same manner as above.

### (Characteristics of the Solar Cells)

Pseudo-sunlight of AM 1.5 was emitted onto the solar cells manufactured as above, and the photoelectric conversion efficiencies at room temperature were evaluated. The results of the evaluation showed that the photoelectric conversion efficiency of the CdTe solar cell with an SiO₂ microscope structure and dots had a preferred value of 9.0%. On the other hand, the photoelectric conversion efficiency of the CdTe solar cell that had dots but did not have an SiO₂ microscope structure was 8.3%.

According to the above described embodiments, the peak wavelength of electric field enhancement caused by the end portions of the second metal layer in a mesh-like state or a particulate state can shift to shorter wavelengths. Accordingly, a visible wavelength in a photoelectric converting layer of a solar cell or the like can be photoelectrically converted, and a higher conversion efficiency can be achieved.

While certain embodiments have been described, these embodiments have been presented by way of example only, and are not intended to limit the scope of the inventions. Indeed, the novel methods and systems described herein can be embodied in a variety of other forms; furthermore, various omissions, substitutions and changes in the form of the methods and systems described herein can be made without departing from the spirit of the inventions. The accompanying claims and their equivalents are intended to cover such forms or modifications as would fall within the scope and spirit of the inventions.

What is claimed is:

1. A photoelectric conversion element comprising:
a first metal layer;
a semiconductor layer formed on the first metal layer;
a second metal layer formed on the semiconductor layer, the second metal layer comprising a porous thin film with a plurality of openings each having a mean area not smaller than 80 nm² and not larger than 0.8 μm² or miniature structures having a mean volume not smaller than 4 nm³ and not larger than 0.52 μm³; and
a wavelength converting layer formed between the semiconductor layer and the second metal layer, at least a refractive index of a portion of the wavelength converting layer being lower than a refractive index of a material of the semiconductor layer, the portion being at a distance of 5 nm or shorter from an end portion of the second metal layer.

2. The element according to claim 1, wherein
the wavelength converting layer includes first portions made of a material with a lower refractive index than the refractive index of the material of the semiconductor layer or made of the air, and second portions with a refractive index equal to or lower than the refractive index of the semiconductor layer,
at least a part of the first portions are located at a distance of 5 nm or shorter from the end portion of the second metal layer,
a mean size of at least the part of the first portions in a cross-section perpendicular to a stacking direction of the first metal layer and the semiconductor layer is not smaller than 1 nm and not larger than 100 nm, and
a mean thickness of at least the part of the first portions is not smaller than 10 nm and not greater than 100 nm.

3. The element according to claim 1, wherein the wavelength converting layer is a film made of a material with a lower refractive index than the refractive index of the material of the semiconductor layer, and has a thickness not smaller than 1 nm and not greater than 10 nm.

4. The element according to claim 2, wherein
the second metal layer is a porous thin film that has a plurality of openings having a mean size not smaller than 10 nm and not larger than 1 μm, and has a thickness not smaller than 2 nm and not greater than 200 nm, and
a mean width of metal portions existing between two adjacent openings is not smaller than 10 nm and not greater than 1 μm.

5. The element according to claim 2, wherein
the second metal layer is a layer that includes the miniature structures,
a mean distance between adjacent miniature structures has a value equal to or greater than 0.62×(a volume of each one miniature structure)^{1/3} when the volume of each miniature structure is smaller than 4×10⁻³ μm³, and
the mean distance has a value not smaller than 100 nm and not greater than 1 μm when the volume of each miniature structure is equal to or larger than 4×10⁻³ μm³.

6. The element according to claim 4, wherein at least the portion of the wavelength converting layer located at the distance of 5 nm or shorter from the end portion of the second metal layer has a refractive index not lower than 1.3 and not higher than 2.0.

7. The element according to claim 6, wherein at least the portion of the wavelength converting layer located at the distance of 5 nm or shorter from the end portion of the second metal layer is made of SiO₂, SiN, SiON, SiO:F, a-CF, SiO:CH₃, Al₂O₃, MgO, Y₂O₃, or HfO₂.

8. The element according to claim 7, wherein the second metal layer contains at least one material selected from the group consisting of Al, Ag, Au, Cu, Pt, Ni, Co, Cr, and Ti.

9. The element according to claim 2, wherein the first portions or the second portions are arranged in a stripe pattern or a dot pattern, or are pillar-like structures.

10. The element according to claim 8, wherein
the semiconductor layer includes at least a p-type or n-type layer, and
the semiconductor layer is a single-crystalline silicon layer, a polycrystalline silicon layer, an amorphous silicon layer, or a compound semiconductor layer.
